(19) United States
(12) Patent Application Publication
(10) Pub. No.: US 2017/0373656 A1
(43) Pub. Date: Dec. 28, 2017

(54) LOUDSPEAKER-ROOM EQUALIZATION WITH PERCEPTUAL CORRECTION OF SPECTRAL DIPS

(71) Applicant: Dolby Laboratories Licensing Corporation, San Francisco, CA (US)

(72) Inventors: Sunil BHARITKAR, Scotts Valley, CA (US); Charles Q. ROBINSON, Piedmont, CA (US)

(73) Assignee: Dolby Laboratories Licensing Corporation, San Francisco, CA (US)

(21) Appl. No.: 15/543,554

(22) PCT Filed: Feb. 17, 2016
(86) PCT No.: PCT/US2016/018216

§ 371 Date: Jul. 13, 2017

Related U.S. Application Data
(60) Provisional application No. 62/118,369, filed on Feb. 19, 2015.

(51) Int. Cl. H03G 5/16; H04R 29/00; H04R 3/04; H04R 1/40; H04R 3/00

(52) U.S. Cl. CPC H03G 5/165; H04R 29/001; H04R 3/04; H04R 3/005; H04R 1/406

(57) ABSTRACT

A method for generating a perceptual equalization (EQ) filter applicable to an audio signal to equalize the audio signal, including: generating a full EQ filter for use in performing full equalization on the signal; and modifying the frequency-amplitude spectrum of the full EQ filter in accordance with a dip detection threshold function, thereby generating the perceptual EQ filter, where the dip detection threshold function is indicative of minimum perceivable amplitude of each of at least a number of different dips in the frequency-amplitude spectrum of an acoustic signal. Also, a method for equalizing an audio signal, including: generating a full EQ filter for use in performing full equalization on the signal, modifying the frequency-amplitude spectrum of the full EQ filter in accordance with at least one dip detection threshold value, thereby generating a perceptual EQ filter, and applying the perceptual EQ filter to perceptually equalize the signal.

### CROSS-REFERENCE TO RELATED APPLICATION

This application claims priority to U.S. Provisional Application No. 62/118,369, filed 19 Feb. 2015, which is hereby incorporated by reference in its entirety.

### TECHNICAL FIELD

The invention relates to systems and methods for equalizing audio signals for playback, and for generating equalization (EQ) filters useful for performing such equalization. Typical embodiments are systems and methods for generating an equalization (EQ) filter using dip detection thresholds (each determined for a different frequency range), such that the EQ filter is useful to perceptually correct for notches (dips) in the frequency response of a loudspeaker in a room, and/or applying such an EQ filter to equalize an audio signal for playback by the loudspeaker in the room.

### BACKGROUND

In cinema, and home equalization, traditional automated equalization techniques correct both the spectral dips and peaks in a frequency response of a loudspeaker in a room, where the frequency response is a Fourier transform (or other time domain-to-frequency domain transform) of a loudspeaker-room impulse response from the loudspeaker in the room to a microphone (or set of microphones) in the room.

There can be several unintended and negative consequences from equalization which compensates for spectral dips (also known as notches), including: (i) amplifying an audio signal beyond the capability of the amplifier(s) resulting in signal clipping, (ii) delivering an equalized signal to a loudspeaker incapable of large excursions so that playback of the equalized signal will result in audible distortion, (iii) using more power and generating more heat in the playback equipment, (iv) audible timbre artifacts (peaks in the equalized signal spectrum) at listening positions where the spectral dips are inaudible, and (v) audible time domain filtering artifacts (ringing).

Herein, “full” correction (or “full” equalization) denotes equalization (e.g., conventional equalization) which is not “perceptual” correction (as defined below) but which applies correction to at least one frequency subrange of an audio signal (e.g., a speaker feed) to generate an equalized audio signal whose frequency-amplitude spectrum (at least in the at least one frequency subrange) at least substantially matches a target frequency-amplitude spectrum.

In accordance with a class of embodiments of the present invention, dip detection thresholds (each determined for a different frequency range) are used to determine perceptual equalization (EQ) filters (sometimes referred to herein as perceptual correction filters) which are applicable to audio signals to perform perceptual correction of dips in the frequency-amplitude spectra of the signals.

Herein, “perceptual” correction (or “perceptual” equalization) denotes equalization of an audio signal (e.g., a speaker feed) whose frequency-amplitude spectrum has at least one relatively more audible frequency subrange having a first degree of audibility (perceptibility) to a listener (e.g., as determined by a dip detection threshold function of a type described herein), and at least one less audible frequency subrange having a lower degree of audibility to the listener (e.g., as determined by a dip detection threshold function of a type described herein) in the sense that a dip (sometimes referred to herein as a notch) in each said less audible frequency subrange is less audible to the listener than is a similar or identical dip in each said relatively more audible frequency subrange, and perceptual correction of such an audio signal would apply less correction (e.g., no correction) to each less audible frequency subrange of the audio signal than corresponding full correction would apply to said each less audible frequency subrange. Both a perceptual correction filter and a “corresponding” full correction filter are designed to correct (i.e., equalize) an audio signal to generate an equalized audio signal whose frequency-amplitude spectrum (at least in at least one frequency subrange) at least substantially matches a target frequency-amplitude spectrum, and the perceptual correction filter would apply less correction (e.g., no correction) to each less audible frequency subrange of the audio signal than the full correction filter would apply to said each less audible frequency subrange of the acoustic signal. Perceptual correction of dips (e.g., at lower frequencies of the frequency-amplitude spectrum of an audio signal) in accordance with the invention typically provides most or all of the auditory benefit of full correction of the dips, while decreasing the negative consequences of conventional full correction (e.g., perceptual correction of a signal in accordance with the invention may require application of less gain to a frequency subrange of a signal than does corresponding full correction, thereby avoiding introduction of artifacts due to excessive gain application by the full correction).

The inventors have determined from listening evaluations (using critical test content) which compare fully corrected dips and perceptually corrected dips, that there is typically little to no perceived difference to listeners between fully corrected (equalized) and perceptually corrected (equalized) versions of the test signal.

Some existing equalization methods attempt to minimize the negative consequences of dip correction (during equalization) by defining a frequency-dependent maximum amount of gain that can be applied by the equalization filter (in each frequency range of the signal being equalized) to correct for dips in the signal's frequency-amplitude spectrum. However, the gain limit (for each frequency range) is not selected according to perceptual (or other subjective) criteria, and may instead be determined by the performance limits of components in the playback system (e.g., the limit for each frequency range may be a maximum gain for the frequency range which is applicable, e.g., without distortion, by an amplifier of the system).

### BRIEF DESCRIPTION OF EXEMPLARY EMBODIMENTS

In a first class of embodiments, the invention is a method for generating a perceptual equalization (EQ) filter which is applicable to an audio signal to equalize the audio signal, said method including steps of:

generating (e.g., in a conventional manner) data indicative of a full equalization (EQ) filter for use in performing full equalization on the audio signal; and

modifying the frequency-amplitude spectrum of the full EQ filter in accordance with a dip detection threshold function, D(fc, Q), thereby determining the perceptual EQ filter in response to the full EQ filter, and generating data indicative of the perceptual EQ filter, where the dip detection threshold function, D(fc, Q), is indicative of minimum perceivable amplitude of each of at least a number of different dips (sometimes referred to herein as notches) in the frequency-amplitude spectrum of an acoustic signal as perceived by at least one listener, where each of the dips has center frequency, fc, and quality factor, Q.

Typically, the step of modifying the full EQ filter is performed such that the perceptual EQ filter and the full EQ filter are corresponding filters in the sense that each of the perceptual EQ filter and the full EQ filter is designed to equalize the audio signal to generate an equalized audio signal whose frequency-amplitude spectrum (at least in at least one frequency subrange) at least substantially matches a target frequency-amplitude spectrum, but the perceptual EQ filter would apply less correction (e.g., no correction) than would the full EQ filter to at least a low frequency subrange of the frequency-amplitude of the audio signal in which full equalization would have relatively low audibility as determined by the dip detection threshold function, D(fc, Q). In some embodiments in the first class, the low frequency range (e.g., below a specific frequency, f_{C}, where for example, f_{C}=500 Hz) of the perceptual EQ filter is determined by modifying the low frequency range (below the frequency f_{C}) of the full EQ filter, and the perceptual EQ filter's high frequency correction (for frequencies greater than or equal to the frequency f_{C}) is identical to the high frequency correction of the full EQ filter.

For example, in some embodiments in the first class a low frequency range of the full EQ filter is determined by a combination of R filters (sometimes referred to herein as “full EQ component filters”), where R is an integer, each of the full EQ component filters having a peak having a different center frequency, fₖ, in the low frequency range, a quality factor, Qₖ, and a maximum gain value Aₖ(fₖ,Qₖ), where k is an index identifying each of the full EQ component filters (i.e., k=1, . . . , R). The full EQ filter is designed for application to an audio signal to cause the frequency-amplitude spectrum of the resulting equalized signal to match a target frequency-amplitude spectrum. Typically, each of the full EQ component filters is a parametric biquad filter. For each said center frequency, fₖ, and quality factor, Qₖ, a corresponding dip detection threshold, Dₖ(fₖ,Qₖ) is determined (e.g., the dip detection thresholds Dₖ(fₖ,Qₖ) are predetermined during a preliminary operation. The preliminary operation may be a listening test in which perceptual data is obtained from some number of subjects (e.g., 10 subjects) in response to notched and non-notched versions of pink noise. It is well-known that timbre changes are well-discriminated using steady-state pink noise). The gain values Aₖ are indicative of gain applied by the full EQ filter in each frequency subrange (having center frequency, fₖ) of the full EQ filter's low frequency range. Each such embodiment determines a perceptual EQ filter to replace the full EQ filter, such that gain values of the perceptual EQ filter's upper frequency range are identical to gain values of the full EQ filter in said upper frequency range, and includes steps of:

(a) modeling the low frequency range of the perceptual EQ filter as a combination of R perceptual EQ component filters, each corresponding to one of the full EQ component filters, where each of the perceptual EQ component filters has a peak at the center frequency, fₖ of the corresponding full EQ component filter, the same quality factor, Qₖ, as the corresponding full EQ component filter, and a maximum gain value Nₖ(fₖ,Qₖ), where k is an index identifying each of the perceptual EQ component filters (i.e., k=1, . . . , R);

(b) for each of the full EQ component filters, if −Aₖ>Dₖ(Qₖ,fₖ), setting to zero the gain, Nₖ(Qₖ,fₖ), of the corresponding perceptual EQ component filter (i.e., replacing the gain value Aₖ of the full EQ component filter by the gain value Nₖ=0, so that the inventive perceptual EQ filter will not correct (equalize) a dip centered at the frequency fₖ in the frequency-amplitude spectrum of an audio signal. This is desirable since application of the full EQ component filter having a peak at this center frequency would not result in audible correction to the audio signal, since Dₖ is more negative than −Aₖ); and

(c) for each of the full EQ component filters, if −Aₖ≦Dₖ(Qₖ,fₖ), setting the gain, Nₖ(Qₖ,fₖ), of the corresponding perceptual EQ component filter to the value Nₖ(Qₖ,fₖ)=(Aₖ+Dₖ(Qₖ,fₖ)). In other words, if −Aₖ≦Dₖ(Qₖ,fₖ), the gain value Aₖ of the full EQ component filter is replaced by the smaller gain value Nₖ(Qₖ,fₖ)=(Dₖ(Qₖ,fₖ)+Aₖ). In variations on the exemplary embodiments of the invention, if −Aₖ≦Dₖ(Qₖ,fₖ), the gain Nₖ(Qₖ,fₖ) of the corresponding perceptual EQ component filter is set to the value Nₖ(Qₖ,fₖ)=20 log 10(αₖ)+(Aₖ+Dₖ(Qₖ,fₖ)), where each value αₖ is chosen so that 20 log 10(αₖ)≦−Dₖ(Qₖ,fₖ).

The dip detection threshold values, Dₖ(Qₖ,fₖ), are negative numbers (e.g., as are the values of the dip detection threshold function, D(fc, Q), of FIGS. 3-7 which are described below). There is greater listener sensitivity to smaller dips (lower absolute values of Dₖ) at greater dip center frequencies (and lower values of Qₖ).

Thus, in accordance with the exemplary embodiments in the first class, the lower frequency range of the frequency-amplitude spectrum of the inventive perceptual EQ filter is determined by a combination of perceptual EQ component filters each having peak (at a different center frequency fₖ) with maximum gain Nₖ(Qₖ,fₖ), and the upper frequency range of the perceptual EQ filter's frequency-amplitude spectrum is identical to the upper frequency range of the frequency-amplitude spectrum of the corresponding full EQ filter. Typically, each of the perceptual EQ component filters is a parametric biquad filter. In some alternative embodiments, the perceptual EQ component filters are designed in a sub-range of the frequency range in which the dip detection threshold values have been determined (e.g., in a sub-range from 100 Hz to 300 Hz.)

Optionally, the exemplary embodiments in the first class also include a step of:

determining the dip detection threshold, Dₖ(fₖ,Qₖ), for each pair of fₖ and Qₖ values, by interpolation from a set of predetermined dip detection threshold values which have been predetermined in accordance with the invention in a preliminary measurement operation. The predetermined dip detection threshold values themselves determine a dip detection threshold function, D(fc, Q).

Other exemplary embodiments in the first class are identical to those described above, except in that step (c) is replaced by a step of:

(c′) for each of the full EQ component filters, if −Aₖ≦Dₖ(Qₖ,fₖ), setting the gain, Nₖ(Qₖ,fₖ), of the corresponding perceptual EQ component filter to the value Nₖ(Qₖ,fₖ)=Aₖ. In other words, if −Aₖ≦Dₖ(Qₖ,fₖ), the gain value Nₖ of the perceptual EQ component filter is the corresponding gain value Aₖ of the full EQ component filter.

Other exemplary embodiments in the first class are identical to those described above, except in that the dip detection threshold, Dₖ(fₖ,Qₖ) for each center frequency, fₖ, and quality factor, Qₖ, is determined with a confidence interval having an upper bound and a lower bound (i.e., the upper bound is the value Dₖ(fₖ,Qₖ)+C/2, the lower bound is the value Dₖ(fₖ,Qₖ)−C/2, where C is the width of the confidence interval, and Dₖ(fₖ,Qₖ) and C are determined such that there is X % confidence that the true value of Dₖ(fₖ,Qₖ) is within the confidence interval. For example, X % may be equal to 95%), and in that steps (b) and (c) are replaced by the steps of:

(b′) for each of the full EQ component filters, if −Aₖ>Dₖ(Qₖ,fₖ)+C/2, setting to zero the gain, Nₖ(Qₖ,fₖ), of the corresponding perceptual EQ component filter (i.e., replacing the gain value Aₖ of the full EQ component filter by the gain value Nₖ=0, so that the inventive perceptual EQ filter will not correct (equalize) a dip centered at the frequency fₖ in the frequency-amplitude spectrum of an audio signal); and

(c′) for each of the full EQ component filters, if −Aₖ≦[Dₖ(Qₖ,fₖ)−C/2], setting the gain, Nₖ(Qₖ,fₖ), of the corresponding perceptual EQ component filter to the value Nₖ(Qₖ,fₖ)=(Aₖ+Dₖ(Qₖ,fₖ)+C/2). In other words, if −Aₖ≦[Dₖ(Qₖ,fₖ)−C/2], the gain value Aₖ of the full EQ component filter is replaced by the gain value Nₖ(Qₖ,fₖ)=(Dₖ(Qₖ,fₖ)+C/2+Aₖ).

In other exemplary embodiments in the first class, the dip detection threshold function, D(fc, Q), indicates that notches (having typical values of Q) in the frequency-amplitude spectrum of the acoustic signal having center frequencies below a critical frequency (e.g., 100 Hz or 200 Hz) have low audibility. The perceptual EQ filter is determined such that gain values of an upper frequency range (i.e., above the critical frequency) of the frequency-amplitude spectrum of the perceptual EQ filter are at least substantially identical to corresponding gain values in the upper frequency range of the frequency-amplitude spectrum of the full EQ filter, but gain values of a lower frequency range (i.e., below the critical frequency) of the frequency-amplitude spectrum of the perceptual EQ filter are set (e.g., to zero) so that the perceptual EQ filter performs no significant EQ correction (e.g., no EQ correction) to frequency components of the audio signal below the critical frequency.

In typical embodiments, the audio signal to be equalized by the perceptual EQ filter (and the corresponding full EQ filter) is a speaker feed for a loudspeaker, and determination of the full EQ filter may include steps of determining a loudspeaker-room impulse response from the loudspeaker in a room to a microphone (or set of microphones), performing a time domain-to-frequency domain transform (e.g., discrete Fourier transform) on the impulse response to determine the frequency response of the loudspeaker in the room, and generating the full EQ filter to have a frequency-amplitude spectrum which at least substantially matches a difference between a target frequency-amplitude spectrum and the frequency response, in the sense that the difference between the target frequency-amplitude spectrum and the frequency response is at least substantially constant as a function of frequency. Where the audio signal to be equalized is a speaker feed for a loudspeaker, the acoustic signal whose dip audibility is indicated by the dip detection function, D(fc, Q), preferably has characteristics (e.g., frequency range and peak and/or average level) which match those of equalized acoustic signals expected to be emitted from the loudspeaker in the room.

In some embodiments in the first class, the method also includes a step of:

applying the perceptual EQ filter to the audio signal to generate an equalized audio signal (e.g., the audio signal is a speaker feed for a loudspeaker, the equalized audio signal is an equalized speaker feed for the loudspeaker, and application of the perceptual EQ filter to the speaker feed applies less correction for at least one dip in the frequency-amplitude spectrum of the speaker feed than would the corresponding full EQ filter).

Some embodiments in the first class also include a step of:

before modifying the frequency-amplitude spectrum of the full EQ filter in accordance with the dip detection threshold function, D(fc, Q), providing a stimulus signal and notched versions of the stimulus signal to at least one human listener, and determining the dip detection threshold function, D(fc, Q), to be indicative of minimum perceived amplitude of each of a number of different notches of the notched versions of the stimulus signal as perceived by the at least one human listener, where the notched versions of the stimulus signal include N sets of notched signals, wherein each of the notched signals in the “i”th one of the sets has a frequency-amplitude spectrum with a dip at center frequency, fcᵢ, and quality factor, Qᵢ, where N is an integer greater than one and i is an index in the range from 1 through N. Typically, interpolation is performed to determine the minimum perceivable amplitude value of the dip detection threshold function, D(fc, Q), for a dip having any center frequency, fc, in a continuous range of center frequencies, and any quality factor, Q, in a continuous range of quality factor values, from discrete minimum perceivable amplitude values of the dip detection threshold function, D(fc, Q), for dips in a set of N different dips in the frequency-amplitude spectrum of the acoustic signal, where each of the dips in the set has center frequency, fcᵢ, and quality factor, Qᵢ, where N is an integer greater than one and i is an index in the range from 1 through N.

The stimulus signal may be pink noise (or another stimulus signal such as a sweep or pseudo-random noise sequence) played through at least one speaker in a room and captured by at least one microphone in the room (where “room” is used in a broad sense to denote the environment in which each speaker and microphone is located). The pink noise (or other stimulus), and notched versions of the pink noise (or other stimulus) are emitted from each speaker and captured by each microphone.

In a second class of embodiments, the invention is a method for equalizing an audio signal, including steps of:

(a) generating (e.g., in a conventional manner) a full equalization (EQ) filter for use in performing full equalization on the audio signal, and modifying the frequency-amplitude spectrum of the full EQ filter in accordance with at least one dip detection threshold value, thereby generating a perceptual EQ filter in response to the full EQ filter, where each said dip detection threshold value is indicative of minimum perceivable amplitude of a different dip (sometimes referred to herein as a notch) in the frequency-amplitude spectrum of an acoustic signal as perceived by at least one listener, where each said dip has a center frequency, fc, and a quality factor, Q; and

(b) applying the perceptual EQ filter to the audio signal to perceptually equalize said audio signal, thereby generating an equalized audio signal. Typically, application of the perceptual EQ filter to the audio signal applies less correction for at least one dip in the frequency-amplitude spectrum of the audio signal than would the corresponding full EQ filter. Also typically, the audio signal is a speaker feed for a loudspeaker in a room, and application of the perceptual EQ filter to the speaker feed perceptually correct for dips in the frequency response of the loudspeaker in the room.

The perceptual EQ filter may be determined in step (a) in accordance with any embodiment of the inventive method for perceptual EQ filter generation. Typically, step (a) includes a step of modifying the frequency-amplitude spectrum of the full EQ filter in accordance with at least two dip detection threshold values, and each of the dip detection threshold values may be determined in accordance with any embodiment of the inventive method. For example, in some embodiments, each of the dip detection threshold values is a dip detection threshold, Dₖ(fₖ,Qₖ), for a different pair of fₖ and Qₖ values (where each value fₖ is the center frequency of a dip and each value Qₖ is the quality factor of the dip), determined by interpolation from a set of predetermined dip detection threshold values which have been predetermined in accordance with an embodiment of the invention in a preliminary measurement operation. The predetermined dip detection threshold values themselves determine a dip detection threshold function, D(fc, Q).

Some embodiments of the inventive method are performed in home environments (e.g., with the required signal and/or data processing being performed in an AVR or other home theater device) and some embodiments of the inventive method are performed in cinema environments.

Aspects of the invention include a system configured (e.g., programmed) to perform any embodiment of the inventive method, and a computer readable medium (e.g., a disc) which stores code for implementing any embodiment of the inventive method.

In some embodiments, the inventive system is or includes a processor configured (e.g., programmed) to perform an embodiment of the inventive method (e.g., dip detection threshold value determination, and/or perceptual EQ filter generation, and/or equalization in which a perceptual EQ filter is applied to an audio signal). The processor can be a general or special purpose processor (e.g., an audio digital signal processor), and is programmed with software (or firmware) and/or otherwise configured to perform an embodiment of the inventive method. In some embodiments, the inventive system is or includes a general purpose processor, coupled to receive input data (e.g., indicative of a full EQ filter and/or a dip detection threshold function). The processor is programmed (with appropriate software) to generate (by performing an embodiment of the inventive method) output data in response to the input audio data (e.g., output data indicative of a perceptual EQ filter).

### NOTATION AND NOMENCLATURE

Throughout this disclosure, including in the claims, the expression performing an operation “on” signals or data (e.g., filtering, scaling, or transforming the signals or data) is used in a broad sense to denote performing the operation directly on the signals or data, or on processed versions of the signals or data (e.g., on versions of the signals that have undergone preliminary filtering prior to performance of the operation thereon).

Throughout this disclosure including in the claims, the expression “system” is used in a broad sense to denote a device, system, or subsystem. For example, a subsystem that implements a decoder may be referred to as a decoder system, and a system including such a subsystem (e.g., a system that generates X output signals in response to multiple inputs, in which the subsystem generates M of the inputs and the other X−M inputs are received from an external source) may also be referred to as a decoder system.

Throughout this disclosure including in the claims, the following expressions have the following definitions:

speaker and loudspeaker are used synonymously to denote any sound-emitting transducer. This definition includes loudspeakers implemented as multiple transducers (e.g., woofer and tweeter);

speaker feed: an audio signal to be applied directly to a loudspeaker, or an audio signal that is to be applied to an amplifier and loudspeaker in series;

channel (or “audio channel”): a monophonic audio signal;

speaker channel (or “speaker-feed channel”): an audio channel that is associated with a named loudspeaker (at a desired or nominal position), or with a named speaker zone within a defined speaker configuration. A speaker channel is rendered in such a way as to be equivalent to application of the audio signal directly to the named loudspeaker (at the desired or nominal position) or to a speaker in the named speaker zone. The desired position can be static, as is typically the case with physical loudspeakers, or dynamic;

audio program: a set of one or more audio channels and optionally also associated metadata that describes a desired spatial audio presentation;

render: the process of converting an audio program into one or more speaker feeds, or the process of converting an audio program into one or more speaker feeds and converting the speaker feed(s) to sound using one or more loudspeakers (in the latter case, the rendering is sometimes referred to herein as rendering “by” the loudspeaker(s)). An audio channel can be trivially rendered (“at” a desired position) by applying the signal directly to a physical loudspeaker at the desired position, or one or more audio channels can be rendered using one of a variety of virtualization (or upmixing) techniques designed to be substantially equivalent (for the listener) to such trivial rendering. In this latter case, each audio channel may be converted to one or more speaker feeds to be applied to loudspeaker(s) in known locations, which are in general (but may not be) different from the desired position, such that sound emitted by the loudspeaker(s) in response to the feed(s) will be perceived as emitting from the desired position. Examples of such virtualization techniques include binaural rendering via headphones (e.g., using Dolby Headphone processing which simulates up to 7.1 channels of surround sound for the headphone wearer) and wave field synthesis. Examples of such upmixing techniques include ones from Dolby (Pro-logic type) or others (e.g., Harman Logic 7, Audyssey DSX, DTS Neo, etc.); and

audio video receiver (or “AVR”): a receiver in a class of consumer electronics equipment used to control playback of audio and video content, for example in a home theater.

### BRIEF DESCRIPTION OF THE DRAWINGS

FIG. 1 is a set of three graphs. The graph labeled “freq. response” is an average frequency response (magnitude plotted versus frequency) for a speaker in a room (the averaging having been performed over multiple microphones at different positions in the room), the graph labeled “target curve” is a target frequency-amplitude spectrum (magnitude plotted versus frequency) for the speaker in the room, and the graph labeled “filter response” is an equalization filter (gain plotted versus frequency) for the speaker in the room.

FIG. 2 is a symmetric biquad filter (gain in dB plotted versus frequency) which is the inverse of a notch filter applied to reference (non-notched) pink noise in an embodiment of the inventive method for generating a dip detection threshold function, D(fc, Q).

FIG. 3 is a graph of values (and a 95% confidence interval for each plotted value) of a dip detection threshold function, D(fc, Q) determined by an embodiment of the inventive dip detection threshold function determining method (performed in a cinema, with a non-notched stimulus signal having level 85 dBC). The values were determined in pink noise based discrimination tests in a screening room having over 100 seats for screening audiovisual content, with each listener seated at a distance of roughly ⅔ of the room's length from the screen.

FIG. 4 is a graph of values (and a 95% confidence interval for each plotted value) of a dip detection threshold function, D(fc, Q) determined by an embodiment of the inventive dip detection threshold function determining method (performed in a small room, with a non-notched stimulus signal having level 65 dBC).

FIG. 5 is a set of ten interpolation curves, each for a different integer value of Q in the closed interval [1,10]. Each such curve is a plot of the values D(Q,fc) for the indicated integer value of Q. The interpolations were determined from the FIG. 3 values.

FIG. 6 is a set of five interpolation curves, each for a different integer value of Q in the half open interval (10,15]. Each such curve is a plot of the values D(Q,fc) for the indicated integer value of Q. The interpolations were determined from the FIG. 3 values.

FIG. 7 is a set of fifteen interpolation curves, each for a different integer value of Q in the half open interval (15,30]. Each such curve is a plot of the values D(Q,fc) for the indicated integer value of Q. The interpolations were determined from the FIG. 3 values.

FIG. 8 is a graph of the raw amplitude response (labeled “Raw Amplitude Response”) of a loudspeaker measured in a cinema screening room, and the inverses (labeled “P1” and “P2”) of the frequency-amplitude spectra of parametric biquad filters which may be combined to determine the low frequency range of the frequency-amplitude spectrum of an equalization filter for equalizing a speaker feed for the loudspeaker.

FIG. 9 is a graph of the frequency-amplitude spectrum of an unequalized audio signal (curve S2), the frequency-amplitude spectrum of an equalized signal (curve S1) generated by applying a conventional full EQ filter to the signal, and the frequency-amplitude spectrum of an equalized signal (curve S3) generated by applying to the signal a perceptual EQ filter (generated in accordance with an embodiment of the invention from the conventional full EQ filter).

FIG. 10 is a diagram of a system configured to perform an embodiment of the inventive method.

### DETAILED DESCRIPTION OF EXEMPLARY EMBODIMENTS

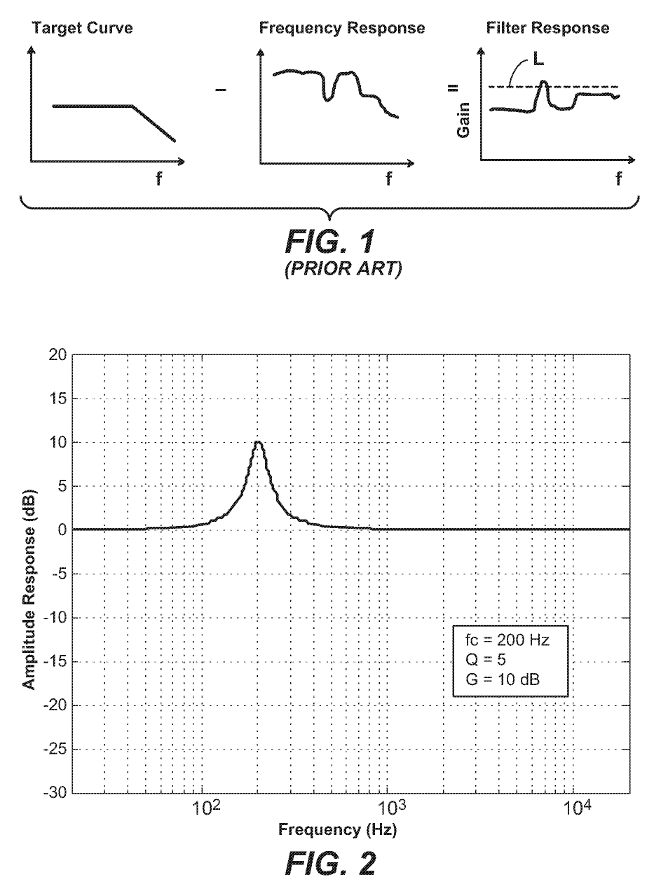

Many embodiments of the present invention are technologically possible. It will be apparent to those of ordinary skill in the art from the present disclosure how to implement them. Embodiments of the inventive system and method will be described with reference to FIGS. 1-10.

The goal in equalizing a cinema or home listening room is to have consistent frequency response from installation to installation, and from position-to-position within an installation (i.e., room). In practice, this involves measuring the loudspeaker-room response, estimating the loudspeaker-room transfer function, and in particular the frequency-amplitude spectrum of the loudspeaker-room response, and selecting an equalization filter (EQ filter) that will align the frequency-amplitude spectrum of the loudspeaker-room response with the desired target (equalized signal) frequency-amplitude spectrum.

Conventional equalization (assuming a single listener position or multiple listener positions) requires measurement of the loudspeaker-room response from each loudspeaker in the room to a microphone at each listener position. In the case of multiple listener positions, the responses for all positions are spatially combined (with smoothing) to determine a spatially combined loudspeaker-room response. After measuring the loudspeaker-room response (e.g., spatially combined loudspeaker-room response) for a speaker, an EQ filter is designed using the loudspeaker-room response, typically by determining the corresponding frequency response (time domain-to-frequency domain transform of the loudspeaker-room impulse response) and designing the EQ filter to be capable of combining with the frequency response to match at least substantially a target (equalized signal) frequency-amplitude spectrum. For example, in the case that the target spectrum is flat, the EQ filter (plotted as gain versus frequency) is at least substantially proportional to the inverse of the loudspeaker-room frequency response.

The EQ filter is then applied (typically by a DSP in the audio signal path, e.g., a DSP in an AVR or cinema processor) to an audio signal to generate an equalized signal for playback by the relevant loudspeaker in the room.

In some embodiments, the invention is a method for generating a perceptual equalization (EQ) filter, where the perceptual EQ filter is applicable to an audio signal to equalize the audio signal, said method including steps of:

generating (e.g., in a conventional manner) data indicative of a full equalization (EQ) filter for use in performing full equalization on the audio signal; and

modifying (e.g., in processing subsystem P2 of audio processing system P of the below-described audio playback system of FIG. 10) the frequency-amplitude spectrum of the full EQ filter in accordance with a dip detection threshold function, D(fc, Q), thereby determining the perceptual EQ filter in response to the full EQ filter, and generating data indicative of the perceptual EQ filter, where the dip detection threshold function, D(fc, Q), is indicative of minimum perceivable amplitude of each of at least a number (a finite number) of different dips (sometimes referred to herein as notches) in the frequency-amplitude spectrum of an acoustic signal as perceived by at least one listener, where each of the dips has center frequency, fc, and quality factor, Q.

Typically, the step of modifying the full EQ filter is performed such that the perceptual EQ filter and the full EQ filter are corresponding filters in the sense that each of the perceptual EQ filter and the full EQ filter is designed to equalize the audio signal to generate an equalized audio signal whose frequency-amplitude spectrum (at least in at least one frequency subrange) at least substantially matches a target frequency-amplitude spectrum, but the perceptual EQ filter would apply less correction (e.g., no correction) than would the full EQ filter to at least a low frequency subrange of the frequency-amplitude of the audio signal in which full equalization would have relatively low audibility as determined by the dip detection threshold function, D(fc, Q).

For example, in some embodiments, the dip detection threshold function, D(fc, Q), indicates that notches (having typical values of Q) in the frequency-amplitude spectrum of the acoustic signal having center frequencies below a critical frequency (e.g., 100 Hz or 200 Hz) have low audibility. The perceptual EQ filter is determined such that gain values of an upper frequency range (i.e., above the critical frequency) of the frequency-amplitude spectrum of the perceptual EQ filter are at least substantially identical to corresponding gain values in the upper frequency range of the frequency-amplitude spectrum of the full EQ filter, but gain values of a lower frequency range (i.e., below the critical frequency) of the frequency-amplitude spectrum of the perceptual EQ filter are set (e.g., to zero) so that the perceptual EQ filter performs no significant EQ correction (e.g., no EQ correction) to frequency components of the audio signal below the critical frequency.

In typical embodiments, the audio signal to be equalized by the perceptual EQ filter (and the corresponding full EQ filter) is a speaker feed for a loudspeaker, and determination of the full EQ filter may include steps of determining a loudspeaker-room impulse response from the loudspeaker in a room to a microphone (or set of microphones), performing a time domain-to-frequency domain transform (e.g., discrete Fourier transform) on the impulse response to determine the frequency response of the loudspeaker in the room, and generating the full EQ filter to have a frequency-amplitude spectrum which at least substantially matches a difference between a target frequency-amplitude spectrum and the frequency response, in the sense that the difference between the target frequency-amplitude spectrum and the frequency response is at least substantially constant as a function of frequency. Where the audio signal to be equalized is a speaker feed for a loudspeaker, the acoustic signal whose dip audibility is indicated by the dip detection function, D(fc, Q), preferably has characteristics (e.g., frequency range and peak and/or average level) which match those of equalized acoustic signals expected to be emitted from the loudspeaker in the room.

In some embodiments, the method also includes a step of:

applying the perceptual EQ filter to the audio signal (e.g., in subsystem E of audio processing system P of the below-described FIG. 10 system) to generate an equalized audio signal (e.g., the audio signal is a speaker feed for a loudspeaker, the equalized audio signal is an equalized speaker feed for the loudspeaker, and application of the perceptual EQ filter to the speaker feed applies less correction for at least one dip in the frequency-amplitude spectrum of the speaker feed than would the corresponding full EQ filter).

In other embodiments, the invention is a method for equalizing an audio signal, including steps of:

(a) generating (e.g., in a conventional manner) a full equalization (EQ) filter for use in performing full equalization on the audio signal, and modifying the frequency-amplitude spectrum of the full EQ filter (e.g., in subsystem P2 of audio processing system P of the below-described audio playback system of FIG. 10) in accordance with at least one dip detection threshold value, thereby generating a perceptual EQ filter in response to the full EQ filter, where each said dip detection threshold value is indicative of minimum perceivable amplitude of a different dip (sometimes referred to herein as a notch) in the frequency-amplitude spectrum of an acoustic signal as perceived by at least one listener, where each said dip has a center frequency, fc, and a quality factor, Q; and

(b) applying the perceptual EQ filter to perceptually equalize the audio signal, thereby generating an equalized audio signal (e.g., in subsystem E of audio processing system P of the below-described FIG. 10 system). Typically, application of the perceptual EQ filter to the audio signal applies less correction for at least one dip in the frequency-amplitude spectrum of the audio signal than would the corresponding full EQ filter. Also typically, the audio signal is a speaker feed for a loudspeaker in a room, and application of the perceptual EQ filter to the speaker feed perceptually correct for dips in the frequency response of the loudspeaker in the room.

The perceptual EQ filter may be determined in step (a) in accordance with any embodiment of the inventive method for perceptual EQ filter generation. Typically, step (a) includes a step of modifying the frequency-amplitude spectrum of the full EQ filter in accordance with at least two dip detection threshold values, and each of the dip detection threshold values may be determined in accordance with any embodiment of the inventive method (e.g., in processing subsystem P1 of audio processing system P of the below-described FIG. 10 system). For example, in some embodiments, each of the dip detection threshold values is a dip detection threshold, Dₖ(fₖ,Qₖ), for a different pair of fₖ and Qₖ values (where each value fₖ is the center frequency of a dip and each value Qₖ is the quality factor of the dip), determined by interpolation from a set of predetermined dip detection threshold values which have been predetermined in accordance with an embodiment of the invention in a preliminary measurement operation. The predetermined dip detection threshold values themselves determine a dip detection threshold function, D(fc, Q).

The number of measurement positions employed to determine a loudspeaker-room response is typically chosen depending on the dimensions and acoustical properties of the room, size of the seating area (e.g., cinemas typically require 5 or more positions, whereas typical consumer domestic listening/viewing environments require at most 5 or 6 positions), and use case (an edit room or dub stage may use fewer microphones placed near the user's seating location).

In some embodiments of the invention, a loudspeaker-room response is determined for each of L loudspeakers to be equalized (where “loudspeaker” is used in a broad sense to denote a single speaker or an array of multiple speakers). A stimulus signal is played by each of the loudspeakers and the output of each speaker (in response to the stimulus) is recorded by each of N microphones, resulting in L*N recordings, where L and N are integers. The stimulus signal is typically an exponential tone sweep, typically having the following parameters:
Sample rate: 48 kHz
Duration: 5 seconds
Start frequency: 2 Hz
End frequency: 24 kHz
Peak level: −30 dBFS
   Alternatively, the stimulus signal is wide-band pink noise.

When the stimulus is a tone sweep, the impulse response for each loudspeaker is obtained by convolving the recorded sweep with the inverse sweep, where the inverse sweep is a time-reversed copy of the stimulus (typically with 3 dB/Octave attenuation). It is well known how to so determine an impulse response, and for example, one such impulse response measurement technique (with an exponential tone sweep) is described in the paper by A. Farina, entitled “Simultaneous measurement of impulse response and distortion with a swept-sine technique,” presented at the 108^{th} AES convention, Paris, February 2000. For efficient processing, the recorded sweep is converted to the frequency domain (typically using a DFT) and the convolution with the inverse sweep is performed as a multiplication in the frequency domain.

When multiple microphones are employed to record the loudspeaker's output in response to the stimulus, available, an average frequency response (Ā) can be determined from the individual frequency responses (A), each determined using a different one of the microphones, by taking the RMS value across the microphones in each frequency bin as follows:

$$\overline{A} ( {f}_{i} ) = \sqrt{\frac{{\sum }_{j = 1}^{{N}_{mics}} {A}_{j}^{2} ( {f}_{i} )}{{N}_{mics}}}$$

The value, Ā(fᵢ), in the preceding equation is the value (in the “i”th frequency bin) of the average frequency response for one loudspeaker in the room, where N_{mics} is the number of microphones, index i identifies the frequency bin, and the average for each frequency bin is over all the microphones.

Alternatively, dB averaging can be used to determine an average frequency response for each loudspeaker in the room.

Once the average frequency response (for a speaker in a room) has been determined, it is well known how to determine a conventional equalization filter (for the speaker in the room) so that its frequency-amplitude spectrum matches the difference between a target frequency-amplitude spectrum and the average frequency response, e.g., as shown in FIG. 1. In FIG. 1, the graph labeled “target curve” is the target frequency-amplitude spectrum, the graph labeled “freq. response) is the average frequency response, and the graph labeled “filter response” is the equalization filter. Each gain value of the equalization filter, for a specific frequency, is at least substantially equal to the difference between the target frequency-amplitude spectrum value at the frequency and the computed average response value at the frequency.

It is conventional to modify a first equalization (EQ) filter to limit the gains thereof (the gain of the first EQ filter, for each of a number of different frequency ranges), thus determining a gain-limited EQ filter whose gain in each frequency range is the greater of: the gain of the first EQ filter in the frequency range; and a predetermined, maximum allowed gain for the frequency range. For example, the limit for each frequency range may be based on known characteristics of playback system components, e.g., the maximum gain (for a frequency range) may be the greatest gain which is applicable (for the frequency range) without unacceptable distortion by an amplifier of the system. The maximum gain “L” superimposed on the EQ filter of FIG. 1 is an example of a maximum allowed gain (in the FIG. 1 example, the same maximum gain, L, applies to all frequency ranges) which may be used to determine a gain-limited EQ filter to replace the EQ filter of FIG. 1.

In accordance with typical embodiments of the invention, gain limits (a gain limit for each frequency range of an EQ filter) are perceptually derived (i.e., the gain limit for each range of frequencies is derived perceptually) as follows. First, measurements are made of the sensitivity of human hearing to dips (notches) in the frequency-amplitude spectrum of a wideband acoustic signal (a stimulus signal), to determine the dip detection threshold, D(fc, Q), as a function of the center frequency fc (in Hz) and quality factor Q of each dip. For each dip in the frequency-amplitude spectrum of an acoustic signal, the value of the detection threshold, D(fc, Q), is the minimum perceivable amplitude (in units of dB) of the dip in the frequency-amplitude spectrum of the acoustic signal, where fc is the center frequency of the dip and Q is the quality factor of the dip. Then, the full EQ filter is modified in accordance with the dip detection threshold function, D(fc, Q), thereby generating a perceptual EQ filter in response to the unmodified full EQ filter.

We next describe an example of a measurement method which uses notched and un-notched versions of a pink noise stimulus signal to determine such a dip detection threshold function, D(fc, Q). In the example, the function D(fc, Q) is determined such that the value of the function D(fc, Q), for each specific quality factor Q and center frequency pair, is the minimum perceivable amplitude of a notch (having quality factor Q and center frequency fc, and which is introduced in the frequency-amplitude spectrum of the stimulus signal) for which a listener (e.g., an average over a set of listeners) in a cinema perceives a timbre change between the un-notched stimulus signal and the notched version of the stimulus resulting from insertion of the notch into its frequency-amplitude spectrum. More specifically, the un-notched stimulus signal in the example is pink noise having reference level 85 dBC. Pink noise is considered a reliable test stimulus for timbre discriminating tests.

In the example, prior to conducting discrimination tests, 85 dBC was set as the playback level at a reference listening position for the stimulus signal played by a center loudspeaker at the front of the cinema. Although a continuous range of frequencies and Q's was available, a small set of notches (all having notch center frequencies below 500 Hz) was selected for insertion (into the stimulus signal's frequency-amplitude spectrum) in the tests. This was because the inventors had found in pilot tests with a small set of listeners that dip detection threshold curves asymptotically converge to 0 dB for notches above 500 Hz, and the inventors had recognized that most of the important room acoustical-related variations in the amplitude response would be observable in the lower frequencies that are likely to be corrected the most (during equalization) with high-gain corrections.

As described below, after the performance of measurements using the selected small set of notches, interpolation techniques were used to determine (from the measurements) dip detection thresholds for notches at arbitrary center frequencies for any given Q. Given that the measurements were conducted at 85 dBC, which is a typical reference level in cinemas, the measurement results were easily mappable by interpolation between two extreme playback levels (e.g., 70 dBC and 95 dBC). The goal of the listening test was to get the listeners to identify at what levels was there a perceptible timbre change between reference (un-notched pink noise) and notched audio (notched pink noise). Given that the tests did not include visual stimuli (i.e., image/video content) and involved critical listeners, it is assumed that naïve listener results would likely be lower-bounded (in magnitude) by the detection results from the tests, in the sense that detection thresholds among naïve and joint audio/visual tests would be higher.

In the example, each dip (notch) was introduced by applying a symmetric biquad filter (e.g., a filter whose frequency-amplitude spectrum is the inverse of that shown in FIG. 2) to the reference (non-notched) pink noise. Alternatively, asymmetric filters could have been applied to synthesize the processed (notched) pink-noise content since theory predicts the presence of asymmetric auditory filters in human hearing (see, for example, R. D. Patterson, I. Nimmo-Smith, “Off-frequency listening and auditory filter asymmetry,” Journal Acoust. Soc. Amer., 67(1): 229-245, January 1980.).

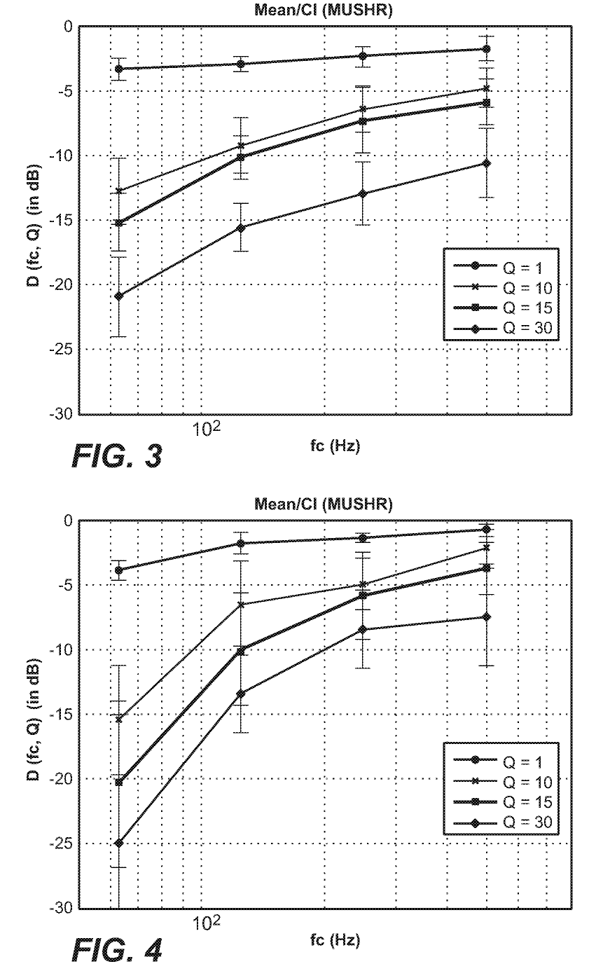

In the example, values of a dip detection threshold function, D(fc, Q) were determined in a cinema (a large room with a high direct-reverberant ratio) with listeners in a direct-dominated position, and with a non-notched pink noise stimulus signal having level 85 dBC. FIG. 3 is a graph of these values (and a 95% confidence interval for each plotted value), plotted (for each of four indicated values of Q) versus notch center frequency, fc (in Hz).

In another example, similar measurements were performed to determine values of a dip detection threshold function, D(fc, Q) in a small room, with a non-notched pink noise stimulus signal having level 65 dBC. FIG. 4 is a graph of these values (and a 95% confidence interval for each plotted value), plotted (for each of four indicated values of Q) versus notch center frequency, fc (in Hz).

As apparent from FIG. 3 for the large room (and from FIG. 4 for the small room), the measured dip detection threshold values show a consistent trend of decreasing threshold of audibility for notches with increasing center frequency and with decreasing Q's (where Q is indicative of notch width) at critical distance. It can be seen that at lower frequencies, dip detection thresholds D(fc, Q) are higher than at higher frequencies in detecting timbre changes. For example, FIG. 3 indicates that for a notch in pink noise at 125 Hz (and Q=15), the notch would need to have a notch depth of at least about −10 dB for the notch to be perceptible to (relative to reference, un-notched pink noise at 85 dBC) to a critical listener at reference position in a room at 85 dBC, but that for a notch in the pink noise at 63 Hz (and Q=15), the notch would need to have a greater notch depth (a notch depth of at least about −15 dB) for the notch to be perceptible to (relative to reference pink noise at 85 dBC) to a critical listener at the same reference position in the room.

To generate the values plotted in FIG. 3 (and those plotted in FIG. 4), a MUSHRA-type procedure (where “MUSHRA” denotes Multiple Stimuli with Hidden Reference and Anchor) was used to determine the conditions of audibility (or inaudibility) of notches processed at various center frequencies and notch depths for a given Q value. Each notch introduced into the pink noise reference signal had one of four values of Q (Q=1, Q=10, Q=15, and Q=30), one of four center frequencies (63 Hz, 125 Hz, 250 Hz, 500 Hz), and one of 18 quantized notch depths (i.e., one of 18 quantized minimum levels relative to the reference level). The room was calibrated with reference pink noise of 85 dBC (65 dBC for the small room) using the front center loudspeaker. The equalization in the B-chain was kept engaged. Each test participant (listener) provided a binary score (100 or 0) to indicate whether he did not hear (or heard) an audible change in the timbre between each pair of two signals (one of which was the non-notched reference signal; the other of which was a notched version of the reference signal with the notch having a specific center frequency, Q value, and notch depth), where a score of 100 indicated no audible change.

There were 10 male participants of diverse age groups (ages in the range from 20's through 60's) approximating a Gaussian age-distribution. Scores obtained from the test were prefiltered prior to statistical analysis to confirm the consistency of each participant in judging the hidden reference correctly over each of the 16 trials. It was determined that two test participants were inconsistent over at least 4 trials in determining the hidden reference. Given such a high proportion of the hidden-reference being misclassified, the scores from the two participants were discarded. The remaining 8 listeners were consistent in correctly classifying the hidden reference.

The test results plotted in FIG. 3 indicate the average measured notch depth thresholds (each of the sixteen plotted threshold values corresponds to the indicated pair of Q and fc values, and is averaged over the perceptual data provided from the listeners in the cinema for such Q and fc values). The plotted values determine a dip detection threshold function, D(fc, Q).

The test results plotted in FIG. 4 indicate the average measured notch depth thresholds (each of the sixteen plotted threshold value corresponds to the indicated pair of Q and fc values, and is averaged over the perceptual data provided from the listeners in the small room for such Q and fc values). The plotted values determine a dip detection threshold function, D(fc, Q).

The test results show that at lower frequencies (less than about 200 Hz), for Q's equal to or greater than 15, dip detection thresholds are high. Consistent with the results, some embodiments of the inventive step of modifying a full EQ filter (e.g., under conditions of such large values of Q) to determine a modified (perceptual) EQ filter are performed so as to prevent unneeded equalization (during application of the modified EQ filter) at lower frequencies. This is especially desirable due to the likelihood that artifacts arising (e.g., in the electrical chain) from overcorrection of notches during equalization will outweigh any barely audible (or inaudible) benefits. For example, in some embodiments of the invention, the inventive perceptual EQ filter applies no gain change to frequency components of an audio signal below about 200 Hz (under conditions of large values of Q, e.g., Q equal to or greater than 15), except (optionally, in some implementations) to correct for resonances or other peaks which occur below 200 Hz, and the inventive perceptual EQ filter applies no more than gentle gain change to frequency components of an audio signal to correct for notches between about 200 Hz and about 500 Hz (under conditions of large values of Q). Any other notches (e.g., due to crossover in the mid-range) may be addressed (if at all) differently.

In typical embodiments of the invention (as in the example), dip detection thresholds (typically averaged over perceptual data obtained from multiple listeners) are obtained for a few discrete Q's and center frequencies, fc. These threshold values determine a dip detection threshold function, D(fc, Q).

When modifying a full EQ filter (e.g., a conventionally determined full EQ filter) to determine a perceptual EQ filter in accordance with some embodiments of the invention, the perceptual EQ filter is determined using an optimization technique to approximate the overall perceptual EQ filter by fitting biquad filters (or asymmetric filters) with arbitrary Q values and center frequencies, fc, to match (except for perceptually-determined differences determined by the dip detection threshold function) the same target frequency-amplitude spectrum which was used to generate the full EQ filter. An interpolation technique is typically employed to determine each needed detection threshold value (of the dip detection threshold function, D(fc, Q)) for each relevant pair of center frequency (fc) and Q values, in order to perform the required determination and fitting of each needed biquad (or asymmetric) filter.

For example, for a given Q, piecewise cubic interpolation over center frequencies may be used to determine the detection threshold value (of the dip detection threshold function, D(fc, Q)) for the relevant center frequency, fc. Alternative interpolation methods that may be used include linear, spline, or arbitrary order polynomial interpolation. After interpolating over frequencies, interpolation over Q may done by simple linear interpolation to determine the dip detection threshold for an arbitrary pair of Q and center frequency values. For example, where the notch depth threshold for one Q value (“Qⱼ”) and center frequency f has been determined to be D(Qⱼ,f), and the notch depth threshold for another Q value (“Qᵢ”) and the same center frequency f has been determined to be D(Qᵢ, f), where indices i, j are in the range {1,10}, or {10,15}, or {15,30}, then an interpolated notch depth threshold value (“D(Q, f)”) for an arbitrary Q in the same range which includes Qᵢ and Qⱼ, and the same center frequency f, may be determined as follows:

ΔD_{Q,f}=(D(Qⱼ,f)−D(Qᵢ,f))/(j−i)

D(Q,f)=D(Qᵢ,f)+ΔD_{Q,f}

i,j={1, 10} or
i,j={10, 15} or
i,j={15, 30}

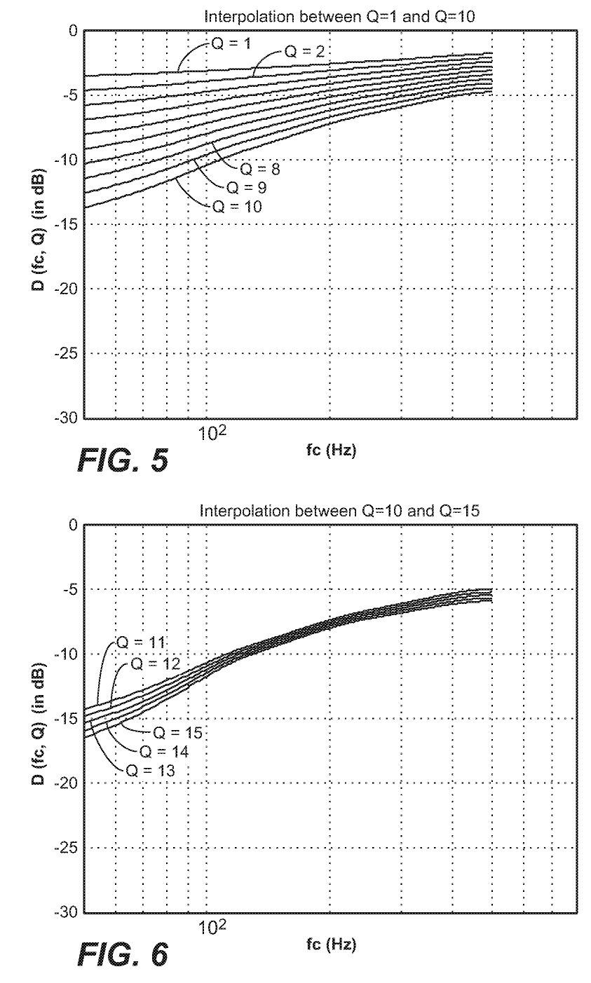

FIG. 5 is a set of ten interpolation curves, each for a different integer value of Q in the closed interval [1,10]. Each such curve is a plot of the values D(Q,fc) for the indicated integer value of Q, and is consistent with the measured notch depth threshold values which are plotted in FIG. 3.

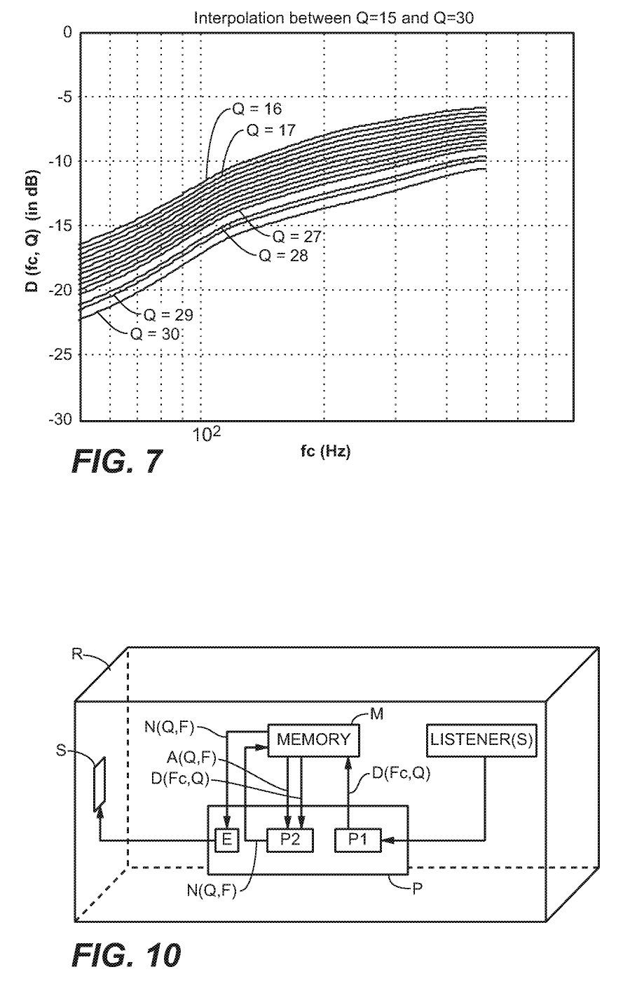

FIG. 6 is a set of five interpolation curves, each for a different integer value of Q in the half open interval (10,15]. Each such curve is a plot of the values D(Q,fc) for the indicated integer value of Q, and is consistent with the measured notch depth threshold values which are plotted in FIG. 3.

FIG. 7 is a set of fifteen interpolation curves, each for a different integer value of Q in the half open interval (15,30]. Each such curve is a plot of the values D(Q,fc) for the indicated integer value of Q, and is consistent with the measured notch depth threshold values which are plotted in FIG. 3.

Perceptual EQ filters having gains, Nₖ(Qₖ,fₖ), where k is an index identifying each different frequency subrange, may be determined and generated in accordance with various embodiments of the invention (from conventionally determined full EQ filters having gains, Aₖ, in the same frequency subranges).

An example of one such perceptual EQ filter generating method (referred to below as “Method 1”) will next be described.

Method 1 assumes that a low frequency range (below a maximum frequency, which may be, for example, 500 Hz) of a full EQ filter (e.g., a conventional full EQ filter) is determined by a combination of R filters (sometimes referred to herein as “full EQ component filters”), each having a peak having a different center frequency, fₖ (in the low frequency range), a quality factor, Qₖ, and a maximum gain value Aₖ(fₖ,Qₖ), where k is an index identifying each of the filters (i.e., k=1, R, where for example, R may be equal to 9). The full EQ filter is designed for application to an audio signal to cause the frequency-amplitude spectrum of the resulting equalized signal to match a target frequency-amplitude spectrum. Typically, each of the full EQ component filters is a parametric biquad filter. For each said center frequency, fₖ, and quality factor, Qₖ, a corresponding dip detection threshold, Dₖ(fₖ,Qₖ) is determined (either the dip detection thresholds are determined as a step of Method 1, or they have been predetermined during a preliminary operation). The gain values Aₖ (which may have units of dB) are indicative of gain applied by the full EQ filter in each frequency subrange (having center frequency, fₖ) of the full EQ filter's low frequency range. The Qk values may be determined in any manner (e.g., in a conventional manner).

Method 1 determines a perceptual EQ filter to replace the full EQ filter, such that gain values of the perceptual EQ filter's upper frequency range (the frequency range above the above-mentioned maximum frequency) are identical to gain values of the full EQ filter in said upper frequency range, and includes the following steps:

(a) modeling the low frequency range of the perceptual EQ filter as a combination of R perceptual EQ component filters, each corresponding to one of the full EQ component filters, where each of the perceptual EQ component filters has a peak at the center frequency, fₖ of the corresponding full EQ component filter, the same quality factor, Qₖ, as the corresponding full EQ component filter, and a maximum gain value Nₖ(fₖ,Qₖ), where k is an index identifying each of the perceptual EQ component filters (i.e., k=1, . . . , R);

(b) for each of the full EQ component filters, if −Aₖ>Dₖ(Qₖ,fₖ), setting to zero the gain, Nₖ(Qₖ,fₖ), of the corresponding perceptual EQ component filter (i.e., replacing the gain value Aₖ of the full EQ component filter by the gain value Nₖ=0, so that the inventive perceptual EQ filter will not correct (equalize) a notch centered at the frequency fₖ in the frequency-amplitude spectrum of an audio signal. This is desirable since application of the full EQ component filter having a peak at this center frequency would not result in audible correction to the audio signal, since Dₖ is more negative than −Aₖ); and

(c) for each of the full EQ component filters, if −Aₖ≦Dₖ(Qₖ,fₖ), setting the gain, Nₖ(Qₖ,fₖ), of the corresponding perceptual EQ component filter to the value Nₖ(Qₖ,fₖ)=(Aₖ+Dₖ(Qₖ,fₖ)). In other words, if −Aₖ≦Dₖ(Qₖ,fₖ), the gain value Aₖ of the full EQ component filter is replaced by the smaller gain value Nₖ(Qₖ,fₖ)=(Dₖ(Qₖ,fₖ)+Aₖ). In variations on the Method 1 embodiment of the invention, if −Aₖ≦Dₖ(Qₖ,fₖ), the gain, Nₖ(Qₖ,fₖ), of the corresponding perceptual EQ component filter is set to the value Nₖ(Qₖ,fₖ)=20 log 10(αₖ)+(Aₖ+Dₖ(Qₖ,fₖ)), where each value αₖ is chosen so that 20 log 10(αₖ)≦−Dₖ(Qₖ,fₖ).

The notch threshold values, Dₖ(Qₖ,fₖ), are negative numbers (e.g., as are the values of the dip detection threshold function, D(fc, Q), of FIGS. 3-7). There is greater listener sensitivity to smaller notches (lower absolute values of Dₖ) at greater notch center frequencies (and lower values of Q), as indicated for example by FIGS. 3-7.

Thus, in accordance with Method 1 (which is an embodiment of the inventive method), the lower frequency range of the frequency-amplitude spectrum of the inventive perceptual EQ filter is determined by a combination of perceptual EQ component filters each having peak (at a different center frequency fₖ) with maximum gain Nₖ(Qₖ,fₖ), and the upper frequency range of the perceptual EQ filter's frequency-amplitude spectrum is identical to the upper frequency range of the frequency-amplitude spectrum of the corresponding full EQ filter. Typically, each of the perceptual EQ component filters is a parametric biquad filter.

Optionally, Method 1 includes a step of:

determining the dip detection threshold, Dₖ(fₖ,Qₖ), for each pair of fₖ and Qₖ values, by interpolation (e.g., interpolation as described above) from a set of predetermined dip detection threshold values which have been predetermined in accordance with the invention in a preliminary measurement operation. The predetermined dip detection threshold values themselves determine a dip detection threshold function, D(fc, Q).

Method 1 has been tested and it has been confirmed that there is no audible difference between a fully corrected signal (a conventionally equalized signal, filtered by a conventional full EQ filter) and a signal corrected (equalized) by the inventive perceptual EQ filter (which has been determined by Method 1 from the conventional full EQ filter by applying perceptually determined modifications to the conventional full EQ filter in the lower frequency subranges).

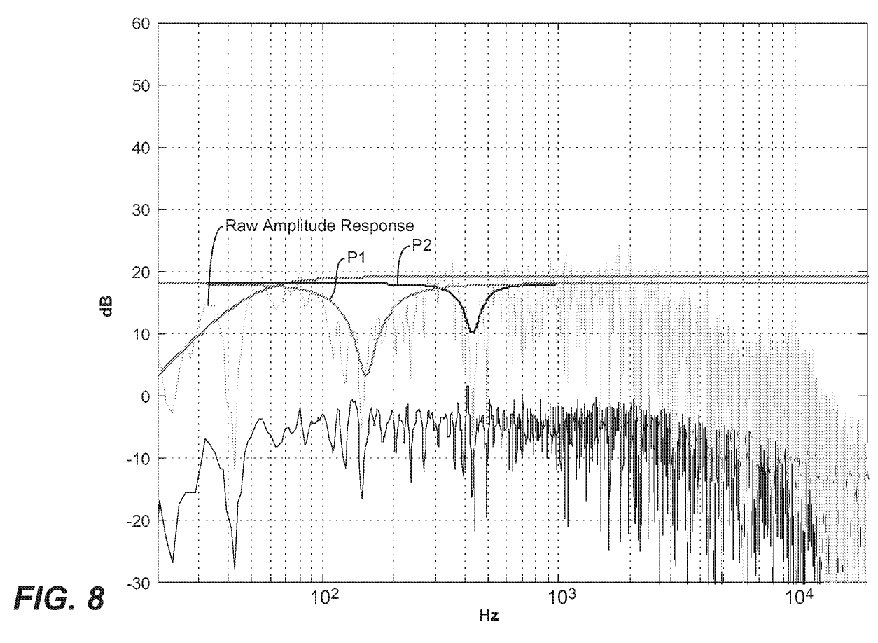

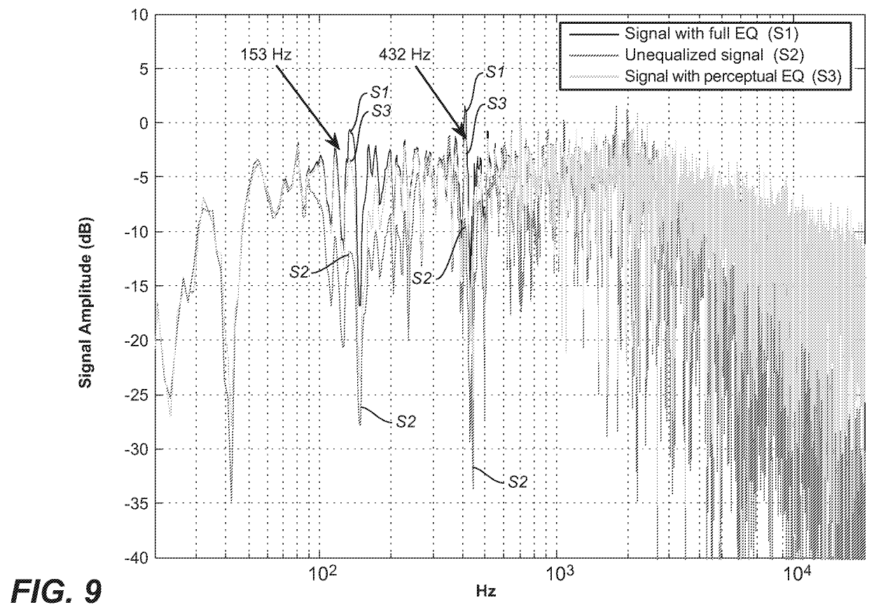

Consider an example of Method 1 with reference to FIGS. 8 and 9.

FIG. 8 is a graph of the raw amplitude response (labeled “Raw Amplitude Response”) of a loudspeaker measured in a cinema screening room. In the example, it is desired to perform equalization so that the equalized response matches a flat target frequency-amplitude spectrum. Thus, a parametric biquad filter (the inverse of curve P1 in FIG. 8) is determined via optimization to correct the dominant dip in the low frequency range of the Raw Amplitude Response at around 150 Hz, a second parametric biquad filter (the inverse of curve P2 in FIG. 8) is determined via optimization to correct the other dominant dip in the low frequency range of the Raw Amplitude Response at around 430 Hz, and a combination of the two parametric biquad filters (a combination of the inverses of P1 and P2) determines the low frequency range of the full EQ filter.

Still with reference to the example of Method 1, the full EQ filter's low frequency range is modeled in step (a) of Method 1 as a combination of a biquad filter having a peak centered at fₖ=153 Hz and a maximum gain Aₖ=15 dB (assuming Qₖ=8), and a second biquad filter having a peak centered at fₖ=432 Hz and a maximum gain Aₖ=8 dB (also assuming Qₖ=8). These are the biquad filters indicated by inverses of curves P1 and P2 of FIG. 8. In the example, Method 1 determines that the low frequency range of the inventive perceptual EQ filter is determined by a combination of a biquad filter having a peak centered at fₖ=153 Hz and a maximum gain Nₖ=Dₖ Aₖ=Dₖ+15 dB=7.8081 dB (assuming Qₖ=8), and a biquad filter having a peak centered at fₖ=432 Hz and a maximum gain Nₖ=Dₖ Aₖ=Dₖ+8 dB=3.7067 dB in the frequency subrange centered at fₖ=432 Hz (also assuming Qₖ=8). Thus, in the two low frequency subranges centered at 153 Hz and 432 Hz, the inventive perceptual EQ filter would apply gain (equalization correction) to an audio signal, but this gain would be less than the gain that would be applied by the full EQ filter. This is desirable because the dip detection threshold values Dₖ for these frequency subranges indicate that the effect of the full EQ filter (in these frequency subranges) would be audible but would have low audibility. Also, because the dip detection threshold values Dₖ for the frequency subranges indicate that the effect of the full EQ filter at fₖ=153 Hz would be less audible than at fₖ=432 Hz, it is desirable that the gain difference between the full EQ filter and the perceptual EQ filter is greater at fₖ=153 Hz than at fₖ=432 Hz.

The values of Nₖ at fₖ=153 Hz and fₖ=432 Hz are consistent with the dip detection threshold values determined by the function D(fc,Q) indicated by FIG. 5, for the same notch center frequency values (fc=153 Hz and fc=432 Hz) and Q=8.

FIG. 9 is a graph of the frequency-amplitude spectrum of an unequalized signal (curve S2), the frequency-amplitude spectrum of an equalized signal (curve S1) generated by applying a conventional full EQ filter (modeled using the biquad filters whose inverses are indicated by curves P1 and P2 of FIG. 8) to the signal, and the frequency-amplitude spectrum of an equalized signal (curve S3) generated by applying to the signal a perceptual EQ filter (generated in accordance with the “Method 1” embodiment of the invention from the conventional full EQ filter). It is apparent from FIG. 9 that the difference between the two equalized signal values (of curves S1 and S3) at 153 Hz is approximately equal to Nₖ−Aₖ=Dₖ=7.8081 dB−15 dB=−7.19 dB and that the difference between the two equalized signal values (of curves S1 and S3) at 432 Hz is approximately equal to Nₖ−Aₖ=Dₖ=3.7067 dB−8 dB=−4.29 dB, and that these values of Dₖ match those determined by the function D(fc,Q) indicated by FIG. 5, for the same notch center frequency values and Q=8.

We next describe an alternative to Method 1, which is another embodiment of the inventive method for generating a perceptual EQ filter, referred to below as “Method 2”.

Method 2 is identical to Method 1, except in that step (c) of Method 1 is replaced (in Method 2) by the step of:

(c′) for each of the full EQ component filters, if −Aₖ≦Dₖ(Qₖ,fₖ), setting the gain, Nₖ(Qₖ,fₖ), of the corresponding perceptual EQ component filter to the value Nₖ(Qₖ,fₖ)=Aₖ. In other words, if −Aₖ≦Dₖ(Qₖ,fₖ), the gain value Nₖ of the perceptual EQ component filter is the corresponding gain value Aₖ of the full EQ component filter.

In both Method 1 and Method 2, if −Aₖ>Dₖ(Qₖ,fₖ), the gain, Nₖ(Qₖ,fₖ), of the corresponding perceptual EQ component filter is set to zero, so that the inventive perceptual EQ filter will not correct (equalize) a notch centered at the frequency fₖ in the frequency-amplitude spectrum of an audio signal. This is desirable since application of the full EQ component filter having a peak at this center frequency would not result in audible correction to the audio signal, since Dₖ is more negative than −Aₖ.

We next describe another alternative to Method 1, which is another embodiment of the inventive method for generating a perceptual EQ filter, referred to below as “Method 3”.

Method 3 is identical to Method 1, except in that the dip detection threshold, Dₖ(fₖ,Qₖ) for each said center frequency, fₖ, and quality factor, Qₖ, is determined (either the dip detection thresholds are determined as a step of Method 3, or they have been predetermined during a preliminary operation) with a confidence interval having an upper bound and a lower bound (i.e., the upper bound is the value Dₖ(fₖ,Qₖ)+C/2, the lower bound is the value Dₖ(fₖ,Qₖ)−C/2, where C is the width of the confidence interval, and Dₖ(fₖ,Qₖ) and C are determined such that there is X % confidence that the true value of Dₖ(fₖ,Qₖ) is within the confidence interval. For example, X % may be equal to 95%), and in that steps (b) and (c) of Method 1 are replaced (in Method 3) by the steps of:

(b′) for each of the full EQ component filters, if −Aₖ>Dₖ(Qₖ,fₖ)+C/2, setting to zero the gain, Nₖ(Qₖ,fₖ), of the corresponding perceptual EQ component filter (i.e., replacing the gain value Aₖ of the full EQ component filter by the gain value Nₖ=0, so that the inventive perceptual EQ filter will not correct (equalize) a notch centered at the frequency fₖ in the frequency-amplitude spectrum of an audio signal); and

(c′) for each of the full EQ component filters, if −Aₖ≦[Dₖ(Qₖ,fₖ)−C/2], setting the gain, Nₖ(Qₖ,fₖ), of the corresponding perceptual EQ component filter to the value Nₖ(Qₖ,fₖ)=(Aₖ+Dₖ(Qₖ,fₖ)+C/2). In other words, if −Aₖ≦[Dₖ(Qₖ,fₖ)−C/2], the gain value Aₖ of the full EQ component filter is replaced by the gain value Nₖ(Qₖ,fₖ)=(Dₖ(Qₖ,fₖ)+C/2+Aₖ).

As noted, in some implementations of Method 3, the confidence interval is determined (i.e., Dₖ(fₖ,Qₖ) and C are determined) such that there is 95% confidence that the true value of Dₖ(fₖ,Qₖ) is within the confidence interval.

In a variation on each of Methods 1, 2, and 3 (and other embodiments of the inventive method), an additional limit is applied to each preliminarily determined gain value Nₖ(Qₖ,fₖ) of a perceptual EQ filter. For example, the additional limit may be implemented as follows: each preliminarily determined gain value Nₖ(Qₖ,fₖ) determined by Method 1, 2 or 3 (or a similar value preliminarily determined by another embodiment of the inventive method) is compared to a fixed maximum allowable gain value L (e.g., L is a constant, and is independent of both Qₖ and fₖ), and if the preliminarily determined value is less than L, then the preliminarily determined value is replaced by the value L. In this way, the gain applied by the inventive perceptual EQ filter during equalization is limited (e.g., to meet amplifier requirements or other playback system requirements).

It is contemplated that many embodiments of the invention assume no knowledge of playback system amplifier capability, and do not try specifically (as in some conventional methods) to limit the gain applied by the inventive perceptual EQ filter where unlimited EQ gain would be beyond the capability of the relevant amplifier. Perceptual equalization in accordance with such embodiments typically applies less equalization gain at frequencies where equalization is relatively less audible (e.g., no equalization gain at frequencies where equalization is not audible), which typically has the effect of limiting the equalization in a manner that avoids artifacts or other problems that might occur in conventional full equalization (e.g., due to gain application in excess of amplifier limits).

In typical embodiments of the invention, equalization with a full EQ filter, in comparison with equalization with a corresponding perceptual EQ filter (determined in accordance with the invention from the full EQ filter), results in no perceptible difference between fully corrected and perceptually corrected signals. Thus applying the perceptual EQ filter (which typically applies less gain in at least one frequency subrange than does the corresponding full EQ filter) is perceptually adequate (in terms of discrimination of timbre) and also ensures that risks of damage due to application of excessively high gain signals in the playback chain are minimized.

Various techniques may be used to generate equalization filters, e.g., to generate perceptual EQ filters in accordance with the invention. One such popular technique involves optimizing a cascade of second-order IIR sections (also known as biquad filters), each having second-order numerator and denominator polynomials, to approximate the amplitude response. The controllable variables of each biquad include the center frequency fc, Q (which is typically proportional to fc and inversely proportional to the −3 dB bandwidth, Δf, i.e., Q is typically proportional to fc/Δf), and gain G which is the gain of the biquad at the center frequency.

FIG. 2 is an example of such a biquad. More specifically, FIG. 2 is the frequency-amplitude spectrum of a symmetric biquad filter (gain in dB plotted versus frequency) having fc=200 Hz, Q=5, and G=10.2. FIG. 2 is the inverse of a notch filter applied to reference (non-notched) pink noise in an embodiment of the inventive method for determining a dip detection threshold function, D(fc, Q), and may be one of the perceptual EQ component filters (or one of the full EQ component filters) determined by an embodiment of above-described Method 1, Method 2, or Method 3.

Next, with reference to FIG. 10, we describe an exemplary embodiment of a system configured to perform embodiments of the inventive method. The FIG. 10 system is an audio playback system installed in room R (which may be, for example, a cinema or home theater room), and includes loudspeaker S, audio processing system P (which is coupled and configured to generate an equalized speaker feed for loudspeaker S), and memory M. In response to perceptual data from each listener of a set of listeners L, processing subsystem P1 of system P is configured to generate dip detection threshold values, Dₖ(fₖ,Qₖ), for pairs of notch center frequency (fₖ) and quality factor (Qₖ) values in accordance with any embodiment of the inventive method. The dip detection threshold values themselves determine a dip detection threshold function, D(fc, Q). The generation of the dip detection threshold values, Dₖ(fₖ,Qₖ), would typically be performed in a preliminary operation (during which each listener L would be present in the room to provide the perceptual data), and the dip detection threshold values, Dₖ(fₖ,Qₖ), and/or data indicative of the dip detection threshold function, D(fc, Q), is pre-stored in memory M (which is coupled to processing subsystem P1 and processing subsystem P2) for use during a subsequent playback operation in which a perceptual EQ filter is generated and/or an audio signal is equalized using such a perceptual EQ filter. Of course, the dip detection threshold values (and/or dip detection threshold function) and/or a perceptual EQ filter could be generated (in accordance with an embodiment of the invention) in a preliminary operation in another environment, and the perceptual EQ filter could be pre-stored in subsystem E (or a memory coupled thereto) for use to equalize an audio signal during a subsequent playback operation.

In operation to generate a perceptual EQ filter, data indicative of the dip detection threshold values, Dₖ(fₖ,Qₖ), and/or the dip detection threshold function, D(fc, Q), is asserted from memory M (or from subsystem P1) to processing subsystem P2 of system P. Also, data indicative of a full EQ filter (“A(Q,f)”) is asserted (e.g., from memory M) to processing subsystem P2. In some embodiments, the latter data is indicative of a combination of R filters (sometimes referred to herein as “full EQ component filters”), where R is an integer, each having a peak having a different center frequency, fₖ in the low frequency range, a quality factor, Qₖ, and a maximum gain value Aₖ(fₖ,Qₖ), where k is an index identifying each of the full EQ component filters (i.e., k=1, R, where for example, R may be equal to 9). The full EQ filter is designed for application to an audio signal (a speaker feed for loudspeaker S) to cause the frequency-amplitude spectrum of the resulting equalized signal to match a target frequency-amplitude spectrum.

Processing subsystem P2 is coupled and configured to generate data indicative of a perceptual EQ filter (“N(Q,f)”) in response to the data indicative of the full EQ filter and the data indicative of the dip detection threshold values, Dₖ(fₖ,Qₖ), and/or the dip detection threshold function, D(fc, Q), in accordance with any embodiment of the inventive method for generating a perceptual EQ filter. Subsystem P2 is coupled and configured to store in memory M the data indicative of the perceptual EQ filter. The perceptual EQ filter is designed for application to an audio signal (a speaker feed for loudspeaker S) to cause the frequency-amplitude spectrum of the resulting equalized signal to match the same target frequency-amplitude spectrum mentioned in the previous paragraph.

In operation to equalize an audio signal, data indicative of the perceptual EQ filter (N(Q,f)) is asserted from memory M (or from subsystem P2) to subsystem E. Subsystem E is coupled and configured to generate a speaker feed for loudspeaker S (e.g., by playing a pre-recorded audio or audiovisual program), and to perform equalization on the speaker feed by applying the perceptual EQ filter to the speaker feed to generate an equalized audio signal (an equalized speaker feed) whose frequency-amplitude spectrum (at least in at least one frequency subrange) at least substantially matches the same target frequency-amplitude spectrum mentioned in the two previous paragraphs.

Aspects of the present invention include a system configured (e.g., programmed) to perform any embodiment of the inventive method, and a computer readable medium (e.g., a disc) which stores code for implementing any embodiment of the inventive method. For example, such a computer readable medium may be included in processor P of FIG. 10.

In some embodiments, the inventive system is or includes at least one processor (e.g., processor 2 of FIG. 10). The processor can be or include a general or special purpose processor (e.g., an audio digital signal processor) which is programmed with software (or firmware) and/or otherwise configured to perform an embodiment of the inventive method. In some embodiments, the processor of the inventive system is audio digital signal processor (DSP) which is a conventional audio DSP that is configured (e.g., programmed by appropriate software or firmware, or otherwise configured in response to control data) to perform any of a variety of operations on data including an embodiment of the inventive method.

In some embodiments of the inventive method, some or all of the steps described herein are performed simultaneously or in a different order than specified in the examples described herein. Although steps are performed in a particular order in some embodiments of the inventive method, some steps may be performed simultaneously or in a different order in other embodiments.

While specific embodiments of the present invention and applications of the invention have been described herein, it will be apparent to those of ordinary skill in the art that many variations on the embodiments and applications described herein are possible without departing from the scope of the invention described and claimed herein. It should be understood that while certain forms of the invention have been shown and described, the invention is not to be limited to the specific embodiments described and shown or the specific methods described.

What is claimed is:

1. A method for generating a perceptual equalization (EQ) filter which is applicable to an audio signal to equalize the audio signal, said method including steps of:
generating data indicative of a full equalization (EQ) filter for use in performing full equalization on the audio signal; and
modifying the frequency-amplitude spectrum of the full EQ filter in accordance with a dip detection threshold function, D(fc, Q), thereby determining the perceptual EQ filter in response to the full EQ filter, and generating data indicative of the perceptual EQ filter, where the dip detection threshold function, D(fc, Q), is indicative of minimum perceivable amplitude of each of at least a number of different dips in the frequency-amplitude spectrum of an acoustic signal as perceived by at least one listener, where each of the dips has center frequency, fc, and quality factor, Q.

2. The method of claim 1, wherein the step of modifying the frequency-amplitude spectrum of the full EQ filter is performed such that the perceptual EQ filter and the full EQ filter are corresponding filters in the sense that each of the perceptual EQ filter and the full EQ filter is designed to equalize the audio signal to generate an equalized audio signal whose frequency-amplitude spectrum, at least in at least one frequency subrange, at least substantially matches a target frequency-amplitude spectrum, but the perceptual EQ filter would apply less correction than would the full EQ filter to at least a low frequency subrange of the frequency-amplitude of the audio signal in which full equalization would have relatively low audibility as determined by the dip detection threshold function.

3. The method of claim 1, wherein the dip detection threshold function, D(fc, Q), indicates that notches in the frequency-amplitude spectrum of the acoustic signal, having typical values of Q and having center frequencies below a critical frequency, have low audibility, and wherein the perceptual EQ filter is determined such that gain values of an upper frequency range, above the critical frequency of the frequency-amplitude spectrum of the perceptual EQ filter are at least substantially identical to corresponding gain values in the upper frequency range of the frequency-amplitude spectrum of the full EQ filter, and gain values of a lower frequency range, below the critical frequency, of the frequency-amplitude spectrum of the perceptual EQ filter are set so that the perceptual EQ filter performs no significant correction to frequency components of the audio signal below the critical frequency.

4. The method of claim 3, wherein the critical frequency is at least substantially equal to 100 Hz.

5. The method of claim 1, wherein gain values of an upper frequency range of the perceptual EQ filter are identical to gain values of the full EQ filter in said upper frequency range, and a low frequency range of the full EQ filter is determined by a combination of R full EQ component filters, where R is an integer, each of the full EQ component filters having a peak having a different center frequency, fₖ, in the low frequency range, a quality factor, Qₖ, and a maximum gain value Aₖ(fₖ,Qₖ), where k is an index identifying each of the full EQ component filters, and wherein for each said center frequency, fₖ, and quality factor, Qₖ, a corresponding dip detection threshold, Dₖ(fₖ,Qₖ) has been determined, said method including steps of:
(a) modeling the low frequency range of the perceptual EQ filter as a combination of R perceptual EQ component filters, each corresponding to one of the full EQ component filters, where each of the perceptual EQ component filters has a peak at the center frequency, fₖ of the corresponding full EQ component filter, the same quality factor, Qₖ, as the corresponding full EQ component filter, and a maximum gain value Nₖ(fₖ,Qₖ), where k is an index identifying each of the perceptual EQ component filters;
(b) for each of the full EQ component filters, if −Aₖ>Dₖ(Qₖ,fₖ), setting to zero the gain, Nₖ(Qₖ,fₖ), of the corresponding perceptual EQ component filter, so that the perceptual EQ filter will not correct a dip centered at the corresponding frequency fₖ in the frequency-amplitude spectrum of the audio signal; and
(c) for each of the full EQ component filters, if −Aₖ≦Dₖ(Qₖ,fₖ), setting the gain, Nₖ(Qₖ,fₖ), of the corresponding perceptual EQ component filter to the value Nₖ(Qₖ,fₖ)=(Aₖ+Dₖ(Qₖ,fₖ)).

6. The method of claim 5, wherein each of the full EQ component filters is a parametric biquad filter.

7. The method of claim 5, also including a step of:
determining the dip detection threshold, Dₖ(fₖ,Qₖ), for each pair of fₖ and Qₖ values, by interpolation from a set of predetermined dip detection threshold values.

8. The method of claim 1, wherein gain values of an upper frequency range of the perceptual EQ filter are identical to gain values of the full EQ filter in said upper frequency range, and a low frequency range of the full EQ filter is determined by a combination of R full EQ component filters, where R is an integer, each of the full EQ component filters having a peak having a different center frequency, fₖ, in the low frequency range, a quality factor, Qₖ, and a maximum gain value Aₖ(fₖ,Qₖ), where k is an index identifying each of the full EQ component filters, and wherein for each said center frequency, fₖ, and quality factor, Qₖ, a corresponding dip detection threshold, Dₖ(fₖ,Qₖ) has been determined, said method including steps of:
(a) modeling the low frequency range of the perceptual EQ filter as a combination of R perceptual EQ component filters, each corresponding to one of the full EQ component filters, where each of the perceptual EQ component filters has a peak at the center frequency, fₖ of the corresponding full EQ component filter, the same quality factor, Qₖ, as the corresponding full EQ component filter, and a maximum gain value Nₖ(fₖ,Qₖ), where k is an index identifying each of the perceptual EQ component filters;
(b) for each of the full EQ component filters, if −Aₖ>Dₖ(Qₖ,fₖ), setting to zero the gain, Nₖ(Qₖ,fₖ), of the corresponding perceptual EQ component filter, so that the perceptual EQ filter will not correct a dip centered at the corresponding frequency fₖ in the frequency-amplitude spectrum of the audio signal; and
(c) for each of the full EQ component filters, if −Aₖ≦Dₖ(Qₖ,fₖ), setting the gain, Nₖ(Qₖ,fₖ), of the corresponding perceptual EQ component filter to the value Nₖ(Qₖ,fₖ)=Aₖ.

9. The method of claim 8, wherein each of the full EQ component filters is a parametric biquad filter.

10. The method of claim 1, wherein gain values of an upper frequency range of the perceptual EQ filter are identical to gain values of the full EQ filter in said upper frequency range, and a low frequency range of the full EQ filter is determined by a combination of R full EQ component filters, where R is an integer, each of the full EQ component filters having a peak having a different center frequency, fₖ, in the low frequency range, a quality factor, Qₖ, and a maximum gain value Aₖ(fₖ,Qₖ), where k is an index identifying each of the full EQ component filters, and wherein for each said center frequency, fₖ, and quality factor, Qₖ, a corresponding dip detection threshold, Dₖ(fₖ,Qₖ) has been determined, and wherein the dip detection threshold, Dₖ(fₖ,Qₖ) for each center frequency, fₖ, and quality factor, Qₖ, is determined with a confidence interval having an upper bound and a lower bound, the upper bound is the value Dₖ(fₖ,Qₖ)+C/2, the lower bound is the value Dₖ(fₖ,Qₖ)−C/2, C is the width of the confidence interval, and Dₖ(fₖ,Qₖ) and C are determined such that there is X % confidence that the true value of Dₖ(fₖ,Qₖ) is within the confidence interval, where X is a number, said method including steps of:
(a) modeling the low frequency range of the perceptual EQ filter as a combination of R perceptual EQ component filters, each corresponding to one of the full EQ component filters, where each of the perceptual EQ component filters has a peak at the center frequency, fₖ of the corresponding full EQ component filter, the same quality factor, Qₖ, as the corresponding full EQ component filter, and a maximum gain value Nₖ(fₖ,Qₖ), where k is an index identifying each of the perceptual EQ component filters;
(b) for each of the full EQ component filters, if −Aₖ>Dₖ(Qₖ,fₖ)+C/2, setting to zero the gain, Nₖ(Qₖ,fₖ), of the corresponding perceptual EQ component filter, so that the perceptual EQ filter will not correct a dip centered at the corresponding frequency fₖ in the frequency-amplitude spectrum of an audio signal; and
(c) for each of the full EQ component filters, if −Aₖ≦[Dₖ(Qₖ,fₖ)−C/2], setting the gain, Nₖ(Qₖ,fₖ), of the corresponding perceptual EQ component filter to the value Nₖ(Qₖ,fₖ)=(Aₖ+Dₖ(Qₖ,fₖ)+C/2).

11. The method of claim 10, wherein each of the full EQ component filters is a parametric biquad filter.

12. The method of claim 1, also including a step of:
applying the perceptual EQ filter to the audio signal to generate an equalized audio signal.

13. The method of claim 12, wherein the audio signal is a speaker feed for a loudspeaker, the equalized audio signal is an equalized speaker feed for the loudspeaker, and application of the perceptual EQ filter to the speaker feed applies less correction for at least one dip in the frequency-amplitude spectrum of the speaker feed than would the full EQ filter.

14. The method of claim 1, also including a step of:
before modifying the frequency-amplitude spectrum of the full EQ filter in accordance with the dip detection threshold function, D(fc, Q), providing a stimulus signal and notched versions of the stimulus signal to at least one human listener, and determining the dip detection threshold function, D(fc, Q), to be indicative of minimum perceived amplitude of each of a number of different notches of the notched versions of the stimulus signal as perceived by the at least one human listener, where the notched versions of the stimulus signal include N sets of notched signals, wherein each of the notched signals in the “i”th one of the sets has a frequency-amplitude spectrum with a dip at center frequency, fcᵢ, and quality factor, Qᵢ, where N is an integer greater than one and i is an index in the range from 1 through N.

15. The method of claim 1, wherein gain values of an upper frequency range of the perceptual EQ filter are identical to gain values of the full EQ filter in said upper frequency range, and a low frequency range of the full EQ filter is determined by a combination of R full EQ component filters, where R is an integer, each of the full EQ component filters having a peak having a different center frequency, fₖ, in the low frequency range, a quality factor, Qₖ, and a maximum gain value Aₖ(fₖ,Qₖ), where k is an index identifying each of the full EQ component filters, and wherein for each said center frequency, fₖ, and quality factor, Qₖ, a corresponding dip detection threshold, Dₖ(fₖ,Qₖ) has been determined, said method including steps of:
(a) modeling the low frequency range of the perceptual EQ filter as a combination of R perceptual EQ component filters, each corresponding to one of the full EQ component filters, where each of the perceptual EQ component filters has a peak at the center frequency, fₖ of the corresponding full EQ component filter, the same quality factor, Qₖ, as the corresponding full EQ component filter, and a maximum gain value Nₖ(fₖ,Qₖ), where k is an index identifying each of the perceptual EQ component filters;
(b) for each of the full EQ component filters, if −Aₖ>Dₖ(Qₖ,fₖ), setting to zero the gain, Nₖ(Qₖ,fₖ), of the corresponding perceptual EQ component filter, so that the perceptual EQ filter will not correct a dip centered at the corresponding frequency fₖ in the frequency-amplitude spectrum of the audio signal; and
(c) for each of the full EQ component filters, if −Aₖ≦Dₖ(Qₖ,fₖ), setting the gain, Nₖ(Qₖ,fₖ), of the corresponding perceptual EQ component filter to the value Nₖ(Qₖ,fₖ)=20 log 10(αₖ)+(Aₖ+Dₖ(Qₖ,fₖ)), where each value αₖ is chosen so that 20 log 10(αₖ)≦−Dₖ(Qₖ,fₖ).

16. A method for equalizing an audio signal, including steps of:
(a) generating a full equalization (EQ) filter for use in performing full equalization on the audio signal, and modifying the frequency-amplitude spectrum of the full EQ filter in accordance with at least one dip detection threshold value, thereby generating a perceptual EQ filter in response to the full EQ filter, where each said dip detection threshold value is indicative of minimum perceivable amplitude of a different dip in the frequency-amplitude spectrum of an acoustic signal as perceived by at least one listener, where each said dip has a center frequency, fc, and a quality factor, Q; and
(b) applying the perceptual EQ filter to the audio signal to perceptually equalize said audio signal, thereby generating an equalized audio signal.

17. The method of claim 16, wherein application of the perceptual EQ filter to the audio signal applies less correction for at least one dip in the frequency-amplitude spectrum of the audio signal than would the full EQ filter.

18. The method of claim 16, wherein step (a) includes a step of modifying the frequency-amplitude spectrum of the full EQ filter in accordance with at least two dip detection threshold values, and each of the dip detection threshold values is a dip detection threshold, Dₖ(fₖ,Qₖ) for a different pair of fₖ and Qₖ values, determined by interpolation from a set of predetermined dip detection threshold values, where k is an index, and for each value of k, the value fₖ is the center frequency of a dip and the value Qₖ is the quality factor of the dip.

19. The method of claim 16, wherein each said dip detection threshold value is determined by a dip detection threshold function, the dip detection threshold function indicates that notches in the frequency-amplitude spectrum of the acoustic signal, having typical values of quality factor Q and having center frequencies below a critical frequency, have low audibility, and wherein the perceptual EQ filter is determined such that gain values of an upper frequency range, above the critical frequency of the frequency-amplitude spectrum of the perceptual EQ filter are at least substantially identical to corresponding gain values in the upper frequency range of the frequency-amplitude spectrum of the full EQ filter, and gain values of a lower frequency range, below the critical frequency, of the frequency-amplitude spectrum of the perceptual EQ filter are set so that the perceptual EQ filter performs no significant correction to frequency components of the audio signal below the critical frequency.

20. The method of claim 19, wherein the critical frequency is at least substantially equal to 100 Hz.

21. The method of claim 16, wherein gain values of an upper frequency range of the perceptual EQ filter are identical to gain values of the full EQ filter in said upper frequency range, and a low frequency range of the full EQ filter is determined by a combination of R full EQ component filters, where R is an integer, each of the full EQ component filters having a peak having a different center frequency, fₖ, in the low frequency range, a quality factor, Qₖ, and a maximum gain value Aₖ(fₖ,Qₖ), where k is an index identifying each of the full EQ component filters, and wherein for each said center frequency, fₖ, and quality factor, Qₖ, a corresponding dip detection threshold, Dₖ(fₖ,Qₖ) has been determined, said method including steps of:
modeling the low frequency range of the perceptual EQ filter as a combination of R perceptual EQ component filters, each corresponding to one of the full EQ component filters, where each of the perceptual EQ component filters has a peak at the center frequency, fₖ of the corresponding full EQ component filter, the same quality factor, Qₖ, as the corresponding full EQ component filter, and a maximum gain value Nₖ(fₖ,Qₖ), where k is an index identifying each of the perceptual EQ component filters;
for each of the full EQ component filters, if −Aₖ>Dₖ(Qₖ,fₖ), setting to zero the gain, Nₖ(Qₖ,fₖ), of the corresponding perceptual EQ component filter, so that the perceptual EQ filter will not correct a dip centered at the corresponding frequency fₖ in the frequency-amplitude spectrum of the audio signal; and
for each of the full EQ component filters, if −Aₖ≦Dₖ(Qₖ,fₖ), setting the gain, Nₖ(Qₖ,fₖ), of the corresponding perceptual EQ component filter to the value Nₖ(Qₖ,fₖ)=(Aₖ+Dₖ(Qₖ,fₖ)).

22. The method of claim 21, wherein each of the full EQ component filters is a parametric biquad filter.

23. A system for determining a perceptual equalization (EQ) filter which is applicable to an audio signal to equalize the audio signal, said system including:
a memory, which stores data indicative of a dip detection threshold function, D(fc, Q), where the dip detection threshold function, D(fc, Q), is indicative of minimum perceivable amplitude of each of at least a number of different dips in the frequency-amplitude spectrum of an acoustic signal as perceived by at least one listener, where each of the dips has center frequency, fc, and quality factor, Q; and
a processing subsystem coupled and configured to access data indicative of a full equalization (EQ) filter for use in performing full equalization on the audio signal, to access the data indicative of the dip detection threshold function, D(fc, Q), to modify the frequency-amplitude spectrum of the full EQ filter in accordance with the dip detection threshold function, D(fc, Q), thereby determining the perceptual EQ filter in response to the full EQ filter, and to generate data indicative of the perceptual EQ filter.

24. The system of claim 23, wherein the processing subsystem is configured to modify the frequency-amplitude spectrum of the full EQ filter such that the perceptual EQ filter and the full EQ filter are corresponding filters in the sense that each of the perceptual EQ filter and the full EQ filter is designed to equalize the audio signal to generate an equalized audio signal whose frequency-amplitude spectrum, at least in at least one frequency subrange, at least substantially matches a target frequency-amplitude spectrum, but the perceptual EQ filter would apply less correction than would the full EQ filter to at least a low frequency subrange of the frequency-amplitude of the audio signal in which full equalization would have relatively low audibility as determined by the dip detection threshold function.

25. The system of claim 23, wherein the dip detection threshold function, D(fc, Q), indicates that notches in the frequency-amplitude spectrum of the acoustic signal, having typical values of Q and having center frequencies below a critical frequency, have low audibility, and wherein the processing subsystem is configured to determine the perceptual EQ filter such that gain values of an upper frequency range, above the critical frequency of the frequency-amplitude spectrum of the perceptual EQ filter are at least substantially identical to corresponding gain values in the upper frequency range of the frequency-amplitude spectrum of the full EQ filter, and gain values of a lower frequency range, below the critical frequency, of the frequency-amplitude spectrum of the perceptual EQ filter are set so that the perceptual EQ filter performs no significant correction to frequency components of the audio signal below the critical frequency.

26. The system of claim 23, wherein gain values of an upper frequency range of the perceptual EQ filter are identical to gain values of the full EQ filter in said upper frequency range, and a low frequency range of the full EQ filter is determined by a combination of R full EQ component filters, where R is an integer, each of the full EQ component filters having a peak having a different center frequency, fₖ, in the low frequency range, a quality factor, Qₖ, and a maximum gain value Aₖ(fₖ,Qₖ), where k is an index identifying each of the full EQ component filters, and wherein for each said center frequency, fₖ, and quality factor, Qₖ, a corresponding dip detection threshold, Dₖ(fₖ,Qₖ) has been determined, and wherein the processing subsystem is configured to:
(a) model the low frequency range of the perceptual EQ filter as a combination of R perceptual EQ component filters, each corresponding to one of the full EQ component filters, where each of the perceptual EQ component filters has a peak at the center frequency, fₖ of the corresponding full EQ component filter, the same quality factor, Qₖ, as the corresponding full EQ component filter, and a maximum gain value Nₖ(fₖ,Qₖ), where k is an index identifying each of the perceptual EQ component filters;
(b) for each of the full EQ component filters, if −Aₖ>Dₖ(Qₖ,fₖ), set to zero the gain, Nₖ(Qₖ,fₖ), of the corresponding perceptual EQ component filter, so that the perceptual EQ filter will not correct a dip centered at the corresponding frequency fₖ in the frequency-amplitude spectrum of the audio signal; and
(c) for each of the full EQ component filters, if −Aₖ≦Dₖ(Qₖ,fₖ), set the gain, Nₖ(Qₖ,fₖ), of the corresponding perceptual EQ component filter to the value Nₖ(Qₖ,fₖ)=(Aₖ+Dₖ(Qₖ,fₖ)).

27. The system of claim 26, wherein each of the full EQ component filters is a parametric biquad filter.

28. The system of claim 23, wherein gain values of an upper frequency range of the perceptual EQ filter are identical to gain values of the full EQ filter in said upper frequency range, and a low frequency range of the full EQ filter is determined by a combination of R full EQ component filters, where R is an integer, each of the full EQ component filters having a peak having a different center frequency, fₖ, in the low frequency range, a quality factor, Qₖ, and a maximum gain value Aₖ(fₖ,Qₖ), where k is an index identifying each of the full EQ component filters, and wherein for each said center frequency, fₖ, and quality factor, Qₖ, a corresponding dip detection threshold, Dₖ(fₖ,Qₖ) has been determined, and wherein the processing subsystem is configured to:
(a) model the low frequency range of the perceptual EQ filter as a combination of R perceptual EQ component filters, each corresponding to one of the full EQ component filters, where each of the perceptual EQ component filters has a peak at the center frequency, fₖ of the corresponding full EQ component filter, the same quality factor, Qₖ, as the corresponding full EQ component filter, and a maximum gain value Nₖ(fₖ,Qₖ), where k is an index identifying each of the perceptual EQ component filters;
(b) for each of the full EQ component filters, if −Aₖ>Dₖ(Qₖ,fₖ), set to zero the gain, Nₖ(Qₖ,fₖ), of the corresponding perceptual EQ component filter, so that the perceptual EQ filter will not correct a dip centered at the corresponding frequency fₖ in the frequency-amplitude spectrum of the audio signal; and
(c) for each of the full EQ component filters, if −Aₖ≦Dₖ(Qₖ,fₖ), set the gain, Nₖ(Qₖ,fₖ), of the corresponding perceptual EQ component filter to the value Nₖ(Qₖ,fₖ)=Aₖ.

29. The system of claim 28, wherein each of the full EQ component filters is a parametric biquad filter.

30. The system of claim 23, wherein gain values of an upper frequency range of the perceptual EQ filter are identical to gain values of the full EQ filter in said upper frequency range, and a low frequency range of the full EQ filter is determined by a combination of R full EQ component filters, where R is an integer, each of the full EQ component filters having a peak having a different center frequency, fₖ, in the low frequency range, a quality factor, Qₖ, and a maximum gain value Aₖ(fₖ,Qₖ), where k is an index identifying each of the full EQ component filters, and wherein for each said center frequency, fₖ, and quality factor, Qₖ, a corresponding dip detection threshold, Dₖ(fₖ,Qₖ) has been determined, and wherein the dip detection threshold, Dₖ(fₖ,Qₖ) for each center frequency, fₖ, and quality factor, Qₖ, is determined with a confidence interval having an upper bound and a lower bound, the upper bound is the value Dₖ(fₖ,Qₖ)+C/2, the lower bound is the value Dₖ(fₖ,Qₖ)−C/2, C is the width of the confidence interval, and Dₖ(fₖ,Qₖ) and C are determined such that there is X % confidence that the true value of Dₖ(fₖ,Qₖ) is within the confidence interval, where X is a number, and wherein the processing subsystem is configured to:
(a) model the low frequency range of the perceptual EQ filter as a combination of R perceptual EQ component filters, each corresponding to one of the full EQ component filters, where each of the perceptual EQ component filters has a peak at the center frequency, fₖ of the corresponding full EQ component filter, the same quality factor, Qₖ, as the corresponding full EQ component filter, and a maximum gain value Nₖ(fₖ,Qₖ), where k is an index identifying each of the perceptual EQ component filters;
(b) for each of the full EQ component filters, if −Aₖ>Dₖ(Qₖ,fₖ)+C/2, set to zero the gain, Nₖ(Qₖ,fₖ), of the corresponding perceptual EQ component filter, so that the perceptual EQ filter will not correct a dip centered at the corresponding frequency fₖ in the frequency-amplitude spectrum of an audio signal; and
(c) for each of the full EQ component filters, if −Aₖ≦[Dₖ(Qₖ,fₖ)−C/2], set the gain, Nₖ(Qₖ,fₖ), of the corresponding perceptual EQ component filter to the value Nₖ(Qₖ,fₖ)=(Aₖ+Dₖ(Qₖ,fₖ)+C/2).

31. The system of claim 30, wherein each of the full EQ component filters is a parametric biquad filter.

32. The system of claim 23, also including an equalization subsystem coupled and configured to apply the perceptual EQ filter to the audio signal to generate an equalized audio signal.

33. The system of claim 32, wherein the audio signal is a speaker feed for a loudspeaker, the equalized audio signal is an equalized speaker feed for the loudspeaker, and application of the perceptual EQ filter to the speaker feed applies less correction for at least one dip in the frequency-amplitude spectrum of the speaker feed than would the full EQ filter.

34. A system for equalizing an audio signal, including:
a processing subsystem coupled and configured to access data indicative of a full equalization (EQ) filter for use in performing full equalization on the audio signal, to access data indicative of at least one dip detection threshold value, and to modify the frequency-amplitude spectrum of the full EQ filter in accordance with said at least one dip detection threshold value, thereby generating a perceptual EQ filter in response to the full EQ filter, where each said dip detection threshold value is indicative of minimum perceivable amplitude of a different dip in the frequency-amplitude spectrum of an acoustic signal as perceived by at least one listener, where each said dip has a center frequency, fc, and a quality factor, Q; and
an equalization subsystem coupled and configured to apply the perceptual EQ filter to the audio signal to perceptually equalize said audio signal, thereby generating an equalized audio signal.

35. The system of claim 34, wherein the processing subsystem is configured to generate the perceptual EQ filter such that application of said perceptual EQ filter to the audio signal applies less correction for at least one dip in the frequency-amplitude spectrum of the audio signal than would the full EQ filter.

36. The system of claim 34, wherein the processing subsystem is configured to modify the frequency-amplitude spectrum of the full EQ filter in accordance with at least two dip detection threshold values, and each of the dip detection threshold values is a dip detection threshold, Dₖ(fₖ,Qₖ) for a different pair of fₖ and Qₖ values, determined by interpolation from a set of predetermined dip detection threshold values, where k is an index, and for each value of k, the value fₖ is the center frequency of a dip and the value Qₖ is the quality factor of the dip.

37. The system of claim 34, wherein each said dip detection threshold value is determined by a dip detection threshold function, the dip detection threshold function indicates that notches in the frequency-amplitude spectrum of the acoustic signal, having typical values of quality factor Q and having center frequencies below a critical frequency, have low audibility, and wherein the processing subsystem is configured to determine the perceptual EQ filter such that gain values of an upper frequency range, above the critical frequency of the frequency-amplitude spectrum of the perceptual EQ filter are at least substantially identical to corresponding gain values in the upper frequency range of the frequency-amplitude spectrum of the full EQ filter, and gain values of a lower frequency range, below the critical frequency, of the frequency-amplitude spectrum of the perceptual EQ filter are set so that the perceptual EQ filter performs no significant correction to frequency components of the audio signal below the critical frequency.

38. The system of claim 34, wherein gain values of an upper frequency range of the perceptual EQ filter are identical to gain values of the full EQ filter in said upper frequency range, and a low frequency range of the full EQ filter is determined by a combination of R full EQ component filters, where R is an integer, each of the full EQ component filters having a peak having a different center frequency, fₖ, in the low frequency range, a quality factor, Qₖ, and a maximum gain value Aₖ(fₖ,Qₖ), where k is an index identifying each of the full EQ component filters, and wherein for each said center frequency, fₖ, and quality factor, Qₖ, a corresponding dip detection threshold, Dₖ(fₖ,Qₖ) has been determined, and wherein the processing subsystem is configured to:
model the low frequency range of the perceptual EQ filter as a combination of R perceptual EQ component filters, each corresponding to one of the full EQ component filters, where each of the perceptual EQ component filters has a peak at the center frequency, fₖ of the corresponding full EQ component filter, the same quality factor, Qₖ, as the corresponding full EQ component filter, and a maximum gain value Nₖ(fₖ,Qₖ), where k is an index identifying each of the perceptual EQ component filters;
for each of the full EQ component filters, if −Aₖ>Dₖ(Qₖ,fₖ), set to zero the gain, Nₖ(Qₖ,fₖ), of the corresponding perceptual EQ component filter, so that the perceptual EQ filter will not correct a dip centered at the corresponding frequency fₖ in the frequency-amplitude spectrum of the audio signal; and
for each of the full EQ component filters, if −Aₖ≦Dₖ(Qₖ,fₖ), set the gain, Nₖ(Qₖ,fₖ), of the corresponding perceptual EQ component filter to the value Nₖ(Qₖ,fₖ)=(Aₖ+Dₖ(Qₖ,fₖ)).

39. The system of claim 38, wherein each of the full EQ component filters is a parametric biquad filter.

40. The system of claim 34, wherein the audio signal is a speaker feed for a loudspeaker, the equalized audio signal is an equalized speaker feed for the loudspeaker, and application of the perceptual EQ filter to the speaker feed applies less correction for at least one dip in the frequency-amplitude spectrum of the speaker feed than would the full EQ filter.

41. The system of claim 34, wherein gain values of an upper frequency range of the perceptual EQ filter are identical to gain values of the full EQ filter in said upper frequency range, and a low frequency range of the full EQ filter is determined by a combination of R full EQ component filters, where R is an integer, each of the full EQ component filters having a peak having a different center frequency, fₖ, in the low frequency range, a quality factor, Qₖ, and a maximum gain value Aₖ(fₖ,Qₖ), where k is an index identifying each of the full EQ component filters, and wherein for each said center frequency, fₖ, and quality factor, Qₖ, a corresponding dip detection threshold, Dₖ(fₖ,Qₖ) has been determined, and wherein the processing subsystem is configured to:
model the low frequency range of the perceptual EQ filter as a combination of R perceptual EQ component filters, each corresponding to one of the full EQ component filters, where each of the perceptual EQ component filters has a peak at the center frequency, fₖ of the corresponding full EQ component filter, the same quality factor, Qₖ, as the corresponding full EQ component filter, and a maximum gain value Nₖ(fₖ,Qₖ), where k is an index identifying each of the perceptual EQ component filters;
for each of the full EQ component filters, if −Aₖ>Dₖ(Qₖ,fₖ), set to zero the gain, Nₖ(Qₖ,fₖ), of the corresponding perceptual EQ component filter, so that the perceptual EQ filter will not correct a dip centered at the corresponding frequency fₖ in the frequency-amplitude spectrum of the audio signal; and
for each of the full EQ component filters, if −Aₖ≦Dₖ(Qₖ,fₖ), set the gain, Nₖ(Qₖ,fₖ), of the corresponding perceptual EQ component filter to the value Nₖ(Qₖ,fₖ)=20 log 10(αₖ)+(Aₖ+Dₖ(Qₖ,fₖ)), where each value αₖ is chosen so that 20 log 10(αₖ)≦−Dₖ(Qₖ,fₖ).
